(19) United States
(12) Patent Application Publication
(10) Pub. No.: US 2017/0023654 A1
(43) Pub. Date: Jan. 26, 2017

(54) OPTICALLY PUMPED MAGNETOMETER AND MAGNETIC SENSING METHOD

(71) Applicant: CANON KABUSHIKI KAISHA, Tokyo (JP)

(72) Inventors: Tetsuo Kobayashi, Kyoto-shi (JP); Yosuke Ito, Kyoto-shi (JP); Sunao Ichihara, Tokyo (JP); Natsuhiko Mizutani, Tokyo (JP)

(21) Appl. No.: 15/203,497

(22) Filed: Jul. 6, 2016

(30) Foreign Application Priority Data
Jul. 21, 2015 (JP) 2015-143805

(51) Int. Cl. G01R 33/26

(52) U.S. Cl. CPC G01R 33/26

(57) ABSTRACT

Provided are an optically pumped magnetometer, comprising: at least one cell containing alkali metal atoms; a pump light optical system configured to cause pump light to enter the cell; a probe light optical system configured to cause probe light to enter the at least one cell so as to intersect with the pump light in the at least one cell; a relaxing light optical system configured to cause a plurality of relaxing lights to enter different positions in an intersection region between the pump light and the probe light; a unit configured to detect the probe light having intersected with the pump light and the plurality of relaxing lights, to thereby output a detection signal; and a unit configured to acquire information on a magnetic field intensity of each of the different positions from the detection signal.

### BACKGROUND OF THE INVENTION

Field of the Invention

The present invention relates to a sensing method and a magnetometer for measuring a magnetic field intensity, and more particularly, to an optically pumped magnetometer and a magnetic sensing method each employing an electron spin or a nuclear spin of an atom.

Description of the Related Art

In Yosuke Itoh et al, “Magnetic field distribution measurement directed to biomagnetism measurement by an optically pumped atomic magnetic sensor using a K-Rb hybrid cell,” Technical Research Report of The Institute of Electronics, Information and Communication Engineers, Vol. 112, No. 479, MBE2012-93, p. 31, March, 2013 (hereinafter referred to as “Itoh et al”), and Japanese Patent Application Laid-Open No. 2011-203133, there are disclosed optically pumped magnetometers. The optically pumped magnetometer disclosed in Itoh et al includes a cell containing alkali metal vapor, a pump light source, and a probe light source. The optically pumped magnetometer is configured to measure a spin of an atomic group, which is rotated with a magnetic field to be measured and polarized with pump light, as a rotation of a polarization plane of probe light. In Itoh et al, there is also disclosed a method of separating and measuring magnetic signals at different positions on an optical path of the probe light by changing an intersection region between the probe light and the pump light for each measurement. In Japanese Patent Application Laid-Open No. 2011-203133, there is also disclosed an example of a magnetic sensor array configured to emit probe light and pump light for each plurality of cells and for each cell.

In the optically pumped magnetometer of Itoh et al, it is necessary to change an intersection region between the probe light and the pump light, and hence magnetic field intensities at different positions on an optical path of the probe light cannot be measured simultaneously.

In the optically pumped magnetometer of Japanese Patent Application Laid-Open No. 2011-203133, magnetic field intensities at different positions on an optical path of the probe light cannot be measured, and further there is a problem in that an apparatus is enlarged due to a configuration in which a detector for a signal is required for each cell.

That is, in the optically pumped magnetometers of Itoh et al and Japanese Patent Application Laid-Open No. 2011-203133, magnetic information of spatially different places on an optical path of the probe light cannot be separated and measured simultaneously using one probe light.

### SUMMARY OF THE INVENTION

It is an object of the present invention to provide an optically pumped magnetometer and a magnetic sensing method, which can separate and simultaneously measure magnetic information of spatially different places with one probe light.

According to one aspect of the present invention, there is provided an optically pumped magnetometer, including: at least one cell containing alkali metal atoms; a pump light optical system configured to cause pump light having a circular polarization component to enter the cell; a probe light optical system configured to cause probe light having a linear polarization component to enter the cell so as to intersect with the pump light in the cell; a relaxing light optical system configured to cause a plurality of relaxing lights for relaxing spin polarization of the alkali metal atom to enter different positions in a region in which the pump light and the probe light intersect with each other; a detection unit configured to detect the probe light having intersected with the pump light and the plurality of relaxing lights, to thereby output a detection signal; and an information acquisition unit configured to acquire information on a magnetic field intensity of each of the different positions from the detection signal, in which at least one of periods or phases of time change in intensity or wavelength of the plurality of relaxing lights is different from one another.

Further features of the present invention will become apparent from the following description of exemplary embodiments with reference to the attached drawings.

### BRIEF DESCRIPTION OF THE DRAWINGS

FIG. 1 is a schematic diagram illustrating a configuration of an optically pumped magnetometer according to the first embodiment of the present invention.

FIG. 2 is a perspective view illustrating a configuration of an optically pumped magnetometer according to the second embodiment of the present invention.

FIG. 3 is a schematic diagram illustrating an example of polarization measurement in the optically pumped magnetometer according to the second embodiment of the present invention.

FIG. 4A is a schematic diagram illustrating an example of a method of modulating relaxing light in the optically pumped magnetometer according to the second embodiment of the present invention.

FIG. 4B is a schematic diagram illustrating an example of the method of modulating relaxing light in the optically pumped magnetometer according to the second embodiment of the present invention.

FIG. 4C is a schematic diagram illustrating an example of the method of modulating relaxing light in the optically pumped magnetometer according to the second embodiment of the present invention.

FIG. 5 is a schematic diagram illustrating an example of the polarization measurement in the optically pumped magnetometer according to the third embodiment of the present invention.

FIG. 6A is a chart illustrating an example of relaxing light modulation in the optically pumped magnetometer according to the third embodiment of the present invention.

FIG. 6B is a chart illustrating an example of the relaxing light modulation in the optically pumped magnetometer according to the third embodiment of the present invention.

FIG. 7 is a perspective view illustrating a configuration of an optically pumped magnetometer according to the fourth embodiment of the present invention.

FIG. 8 is a side view illustrating a configuration of an optically pumped magnetometer according to the fourth embodiment of the present invention.

FIG. 9 is a perspective view illustrating a configuration of an optically pumped magnetometer according to the fifth embodiment of the present invention.

FIG. 10 is a schematic diagram illustrating an example of the polarization measurement in the optically pumped magnetometer according to the fifth embodiment of the present invention.

FIG. 11 is a schematic diagram illustrating a configuration of an optically pumped magnetometer according to the sixth embodiment of the present invention.

FIG. 12A is a schematic diagram illustrating a configuration of a light superposition part in the optically pumped magnetometer according to the sixth embodiment of the present invention.

FIG. 12B is a schematic diagram illustrating a configuration of the light superposition part in the optically pumped magnetometer according to the sixth embodiment of the present invention.

### DESCRIPTION OF THE EMBODIMENTS

Preferred embodiments of the present invention will now be described in detail in accordance with the accompanying drawings.

### The First Embodiment

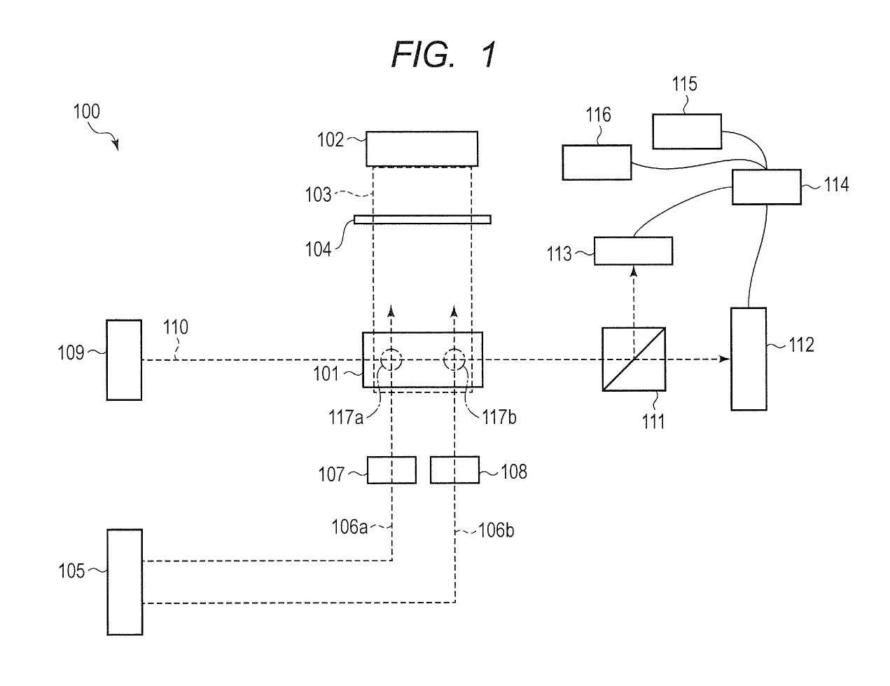

An optically pumped magnetometer and a magnetic sensing method according to the first embodiment of the present invention are described with reference to FIG. 1.

FIG. 1 is a schematic diagram illustrating a configuration of the optically pumped magnetometer according to this embodiment.

First, a schematic configuration of the optically pumped magnetometer according to this embodiment is described with reference to FIG. 1.

As illustrated in FIG. 1, an optically pumped magnetometer 100 according to this embodiment includes a cell 101, an pump light optical system 102, a phase difference plate 104, a relaxing light optical system 105, optical modulators 107 and 108, a probe light optical system 109, a polarization splitter 111, photodetectors 112 and 113, a differential circuit 114, and demodulators 115 and 116. The relaxing light optical system 105 and the optical modulators 107 and 108 herein are sometimes collectively referred to as “relaxing light optical system”.

The pump light optical system 102 is configured to cause pump light 103 to enter a region including measurement regions 117a and 117b of the cell 101 containing alkali metal atoms, e.g., potassium (K) atoms through the phase difference plate 104.

The relaxing light optical system 105 is configured to cause relaxing light 106a to enter the measurement region 117a of the cell 101 through the optical modulator 107. Further, the relaxing light optical system 105 is configured to cause relaxing light 106b to enter the measurement region 117b of the cell 101 through the optical modulator 108. The optical modulators 107 and 108 are modulation units configured to modulate the relaxing lights 106a and 106b, respectively.

The probe light optical system 109 is configured to cause probe light 110 to enter the cell 101. The measurement regions 117a and 117b of the cell 101 are positioned on an optical path of the probe light 110, and the probe light 110 intersects with the pump light 103 and the relaxing lights 106a and 106b in the measurement regions 117a and 117b.

The probe light 110 having passed through the measurement regions 117a and 117b of the cell 101 enters the photodetectors 112 and 113 through the polarization splitter 111. The demodulators 115 and 116 are connected to the photodetectors 112 and 113, respectively, through the differential circuit 114. The polarization splitter 111 and the photodetectors 112 and 113 serve as detectors or detection units configured to detect a rotation angle of the probe light 110 having passed through the cell 101. Further, the difference circuit 114 and the demodulators 115 and 116 serve as calculation units configured to calculate information on magnetic field intensities in the measurement regions 117a and 117b from the rotation angle detected by the detection units or information acquisition units configured to acquire the information. Further, the demodulators 115 and 116 also serve as demodulation units configured to perform demodulation at the same frequency as a modulation frequency used in the modulation units.

Next, the basic operation of the optically pumped magnetometer according to this embodiment is described with reference to FIG. 1.

The pump light 103 output from the pump light optical system 102 is used for aligning the direction of spins of the alkali metal atoms in the cell 101 through optical pumping, to thereby generate spin polarization. For this purpose, the wavelength of the pump light 103 is matched with a wavelength resonated with a D1 transition of the alkali metal atom (hereinafter referred to as “D1 transition resonance wavelength”), and the polarized light of the pump light 103 is converted into circularly-polarized light by the phase difference plate 104. When the polarized light of the light having a D1 transition resonance wavelength is circularly-polarized light, the absorption rate of the circularly-polarized light due to the alkali metal atom depends on the direction of spin polarization, and with this, the optical pumping occurs. As the pump light 103, light from a single light source may be expanded with a lens or the like so that group of atoms in the region including the measurement regions 117a and 117b is subjected to spin polarization. Further, as the pump light 103, light emitted from an independent light source may be used so that each of the group of atoms in the measurement regions 117a and 117b is subjected to spin polarization.

The relaxing lights 106a and 106b output from the relaxing light optical system 105 have the D1 transition resonance wavelength or a wavelength resonated with a D2 transition of the alkali metal atom (hereinafter referred to as “D2 transition resonance wavelength”), and actually, the wavelength can have a range of from about 1 nm to about 10 nm from those transition resonance wavelengths. Therefore, the relaxing lights 106a and 106b serve to relax spin polarization by exciting the spin-polarized alkali metal atoms in the cell 101 through light absorption (T₁ relaxation) or serve to perform phase relaxation (T₂ relaxation). There are two kinds of light that does not serve as relaxing light. One of them is circularly-polarized light which propagates in the same direction as that of the pump light and has the same rotation direction as that of the pump light, and the other is circularly-polarized light which propagates in the opposite direction to that of the pump light and has an opposite rotation direction to that of the pump light.

Any other light serves as relaxing light. Specific examples thereof include A) non-polarized light, B) linearly-polarized light (without regard to a polarization plane), C) circularly-polarized light which propagates in the same direction as that of the pump light and has an opposite rotation direction to that of the pump light, D) circularly-polarized light which propagates in an opposite direction to that of the pump light and has the same rotation direction as that of the pump light, and E) circularly-polarized light in any direction, which propagates in a direction different from that of the pump light. Any of the lights described above excites an electron in both spin states, and hence serve to relax spin polarization created with the pump light. The above-mentioned light A) to light D) relax spin polarization without generating new spin polarization, and hence are suitable for use as relaxing light in the present invention. Meanwhile, the light E) generates new spin polarization, and as the result of the rotation of spin polarization without a magnetic field or under a magnetic field, a polarization plane of the probe light is rotated. Therefore, the light E) is not suitable for use as relaxing light in the present invention.

Of those, as the polarized lights of the relaxing lights 106a and 106b, it is desired to use the linearly-polarized light B) because spin polarization can be relaxed most efficiently. In the case of the linearly-polarized light, the absorption rate of light is constant irrespective of the direction of spin polarization, and the excited alkali metal atoms transition substantially uniformly to two ground levels through spontaneous deexcitation, collision deexcitation with a quencher gas, or the like, with the result that spin polarization is relaxed. Similarly, in order to relax spin polarization, in the case of using the non-polarized light A), it is necessary to prepare light in which the vibration direction of an electric field is temporally random to the extent possible, and the circular polarization degree is 0 on average. Further, in the case of using the circularly-polarized light C) which propagates in the same direction as that of the pump light and has an opposite rotation direction to that of the pump light, or the circularly-polarized light D) which propagates in an opposite direction to that of the pump light and has the same rotation direction as that of the pump light, it is necessary to appropriately adjust the relaxing light intensity so that new spin polarization is not generated. In any of the cases described above, as the relaxing lights 106a and 106b, lights emitted from independent light sources may be used, or light from a single light source may be separated to be used. Further, a part of the light of the pump light optical system 102 may be separated to be used as long as sufficient light intensity is obtained.

The relaxing lights 106a and 106b are modulated at different modulation frequencies in the optical modulators 107 and 108. In this case, it is preferred that the modulation frequencies of the relaxing lights 106a and 106b be frequencies having no harmonic relationship. Further, as the modulation to be applied to the relaxing lights 106a and 106b by the optical modulators 107 and 108, there are given, for example, modulation of light intensity and modulation of a wavelength of the relaxing lights 106a and 106b. Further, modulation may be applied to the relaxing lights 106a and 106b so that a phase of the relaxing light 106a becomes different from that of the relaxing light 106b. That is, in this embodiment, it is appropriate that at least one of periods or phases of time change in intensity or periods of time change in wavelength of a plurality of relaxing lights be different from one another.

The relaxing light optical system 105 may include a light frequency stabilization unit configured to fix the wavelengths of the relaxing lights 106a and 106b to the D1 transition resonance wavelength or the D2 transition resonance wavelength of the alkali metal atom.

As an example of this embodiment, the relaxing light optical system 105 includes the light frequency stabilization unit configured to fix the wavelengths of the relaxing lights 106a and 106b to the D1 transition resonance wavelength (within a range of 770.1 nm±10 nm) of a potassium atom or the D2 transition resonance wavelength (within a range of 766.7 nm±10 nm) of the potassium atom. Alternatively, in the case where the alkali metal atoms in the cell are rubidium, the wavelengths of the relaxing lights 106a and 106b are fixed to the D1 transition resonance wavelength (within a range of 795.0 nm±10 nm) of a rubidium atom or the D2 transition resonance wavelength (within a range of 780.2 nm±10 nm) of the rubidium atom. In the case where the alkali metal atoms in the cell are cesium, the wavelengths of the relaxing lights 106a and 106b are fixed to the D1 transition resonance wavelength of a cesium atom or the D2 transition resonance wavelength of the cesium atom. Further, in the case where the relaxing light intensity is sufficient, the wavelength of the relaxing light may be detuned to some degree from the transition resonance wavelength.

Due to the pump light 103 that enters the cell 101, the alkali metal atoms in the cell 101 are subjected to spin polarization. The spin of the spin-polarized atom receives a torque in accordance with a magnetic field to be measured to perform precession movement. The movement of the spin is represented by the following Bloch equation (Expression (1)). In Expression (1), a vector S(=(Sₓ, S_{y}, S_{z})^{T}) represents the spin of the alkali metal atom, γ represents a gyromagnetic ratio of an electron, q represents a slowdown factor, a vector B represents an external magnetic field, Rₒₚ represents an optical pumping rate of the pump light, s represents a circular polarization degree of the pump light, Rᵣₑₗ(t) represents a relaxing rate of relaxing light, T₁ represents a longitudinal relaxation time, and T₂ represents a transverse relaxation time. The following vectors represent unit direction vectors.

\vec{x}, \vec{y}, \vec{z}
Here, the situation in which the pump light enters from a z direction is considered.

$$\frac{d \vec{S}}{d t} = \frac{γ}{q} \vec{S} \times \vec{B} + \frac{{R}_{op}}{q} ( \frac{s}{2} \vec{z} - \vec{S} ) - \frac{{R}_{rel} ( t )}{q} \vec{S} - \frac{{S}_{x} \vec{x} + {S}_{y} \vec{y}}{{T}_{2}} - \frac{{S}_{z} \vec{z}}{{T}_{1}} \qquad ( 1 )$$

Further, a relaxing rate is represented by the following expression (Expression (2)). In Expression (2), rₑ represents a classical electron radius, c represents a light velocity, f represents an oscillator strength, Iᵣₑₗ represents a relaxing light intensity, ΔΓ represents an absorption line width, h represents Planck's constant, ν represents a relaxing light frequency, and ν₀ represents a resonance frequency of the alkali metal atom.

$${R}_{rel} ( t ) = {r}_{e} cf \frac{{I}_{rel}}{hv} \frac{ΔΓ \text{/} 2}{{( v - {v}_{0} )}^{2} + {( ΔΓ \text{/} 2 )}^{2}} \qquad ( 2 )$$

In Expression (2), when the relaxing light intensity Iᵣₑₗ or the relaxing light frequency ν changes with respect to a time t, the relaxing rate Rᵣₑₗ(t) can be varied. As a specific example thereof, the case where the relaxing rate Rᵣₑₗ(t) of the relaxing light 106a having passed through the optical modulator 107 changes with time in a sine wave form of a modulation frequency ωₐ represented by the following expression (Expression (3)) is considered.

$${R}_{rel} ( t ) = \frac{{R}_{rel}}{2} ( 1 + cos ( {ω}_{a} t ) ) \qquad ( 3 )$$

A spin component S_{z}^{a}(t) in a direction parallel to the relaxing light 106a is determined as a solution to Expression (1) under the situation in which only a magnetic field B_{z} in the z direction exists as a magnetostatic field under the relaxing rate, which changes with time, represented by Expression (3). When the modulation frequency ωₐ of the relaxing light is sufficiently large as compared to the relaxing rate Rᵣₑₗ, quadratic or higher order terms can be ignored regarding Rᵣₑₗ/2qωₐ in the developed expression. With this, the following approximate expression (Expression (4)) can be obtained. In actual measurement, the time t is sufficiently long so that in Expression (4), attenuating terms that do not contribute to the measurement are omitted, and only the steady-state terms are described.

$${S}_{z}^{a} ( t ) ≅ \frac{{sR}_{op}}{\frac{2 q}{{T}_{1}} + 2 {R}_{op} + {R}_{rel}} ( 1 - \frac{{R}_{rel}}{2 q {ω}_{a}} sin ( {ω}_{a} t ) + \frac{{R}_{rel}}{2 q {ω}_{a}} ( \frac{1}{{T}_{1}} + \frac{{R}_{op}}{q} + \frac{{R}_{rel}}{2 q} ) \frac{( \frac{1}{{T}_{1}} + \frac{{R}_{op}}{q} + \frac{{R}_{rel}}{2 q} ) sin ( {ω}_{a} t ) - {ω}_{a} cos ( {ω}_{a} t )}{{( \frac{1}{{T}_{1}} + \frac{{R}_{op}}{q} + \frac{{R}_{rel}}{2 q} )}^{2} + {ω}_{a}^{2}} ) \qquad ( 4 )$$

Under this situation, a small magnetic field in the y direction B₁ is measured at an angular frequency ω. Here, a physical quantity of Ω₁=γ×B₁/q is defined. The spin of the spin-polarized atom receives a torque in accordance with a magnetic field to be measured to perform precession movement. Therefore, a magnetic field can be measured by measuring a spin component Sₓ^{a}(t) in an x direction. The spin component Sₓ^{a}(t) is determined up to the 1st order through use of perturbation regarding Ω₁. Then, attenuating terms are removed therefrom, and steady-state terms are represented by the following expression (Expression (5)).

$${S}_{x}^{a} ( t ) ≅ - \frac{{sR}_{op}}{\frac{4 q}{{T}_{1}} + 4 {R}_{op} + 2 {R}_{rel}} \{ \frac{- ( ω + {Ω}_{0} ) sin ( ω t ) - ( \frac{1}{{T}_{2}} + \frac{{R}_{op}}{2 q} ) cos ( ω t )}{{( \frac{1}{{T}_{2}} + \frac{{R}_{op}}{q} + \frac{{R}_{rel}}{2 q} )}^{2} + {( ω + {Ω}_{0} )}^{2}} + \frac{- ( ω + {Ω}_{0} ) sin ( ω t ) + ( \frac{1}{{T}_{2}} + \frac{{R}_{op}}{2 q} ) cos ( ω t )}{{( \frac{1}{{T}_{2}} + \frac{{R}_{op}}{q} + \frac{{R}_{rel}}{2 q} )}^{2} + {( ω - {Ω}_{0} )}^{2}} \} + \frac{{sR}_{op} {R}_{rel} {Ω}_{1}}{4 q {ω}_{a} ( \frac{4 q}{{T}_{1}} + 4 {R}_{op} + 2 {R}_{rel} )} \{ \frac{- ( ω + {Ω}_{0} ) cos ( ( {ω}_{a} - ω ) t ) - ( \frac{1}{{T}_{2}} + \frac{{R}_{op}}{q} + \frac{{R}_{rel}}{2 q} ) sin ( ( {ω}_{a} - ω ) t )}{{( \frac{1}{{T}_{2}} + \frac{{R}_{op}}{q} + \frac{{R}_{rel}}{2 q} )}^{2} + {( ω + {Ω}_{0} )}^{2}} + \frac{- ( ω + {Ω}_{0} ) cos ( ( {ω}_{a} + ω ) t ) - ( \frac{1}{{T}_{2}} + \frac{{R}_{op}}{q} + \frac{{R}_{rel}}{2 q} ) sin ( ( {ω}_{a} + ω ) t )}{( {( \frac{1}{{T}_{2}} + \frac{{R}_{op}}{q} + \frac{{R}_{rel}}{2 q} )}^{2} + {( ω - {Ω}_{0} )}^{2} )} + \frac{( ω + {Ω}_{0} ) cos ( ( {ω}_{a} + ω ) t ) + ( \frac{1}{{T}_{2}} + \frac{{R}_{op}}{q} + \frac{{R}_{rel}}{2 q} ) sin ( ( {ω}_{a} + ω ) t )}{{( \frac{1}{{T}_{2}} + \frac{{R}_{op}}{q} + \frac{{R}_{rel}}{2 q} )}^{2} + {( ω + {Ω}_{0} )}^{2}} + \frac{- ( ω + {Ω}_{0} ) cos ( ( {ω}_{a} + ω ) t ) + ( \frac{1}{{T}_{2}} + \frac{{R}_{op}}{q} + \frac{{R}_{rel}}{2 q} ) sin ( ( {ω}_{a} + ω ) t )}{( {( \frac{1}{{T}_{2}} + \frac{{R}_{op}}{q} + \frac{{R}_{rel}}{2 q} )}^{2} + {( ω - {Ω}_{0} )}^{2} )} \} \qquad ( 5 )$$

Here, Ω₀(=γ×B_{z}/q) represents a Larmor frequency. The second term of Expression (5) indicates that a response of the spin is modulated at the modulation frequency ωₐ.

Similarly, a response of a spin component Sₓ^{b}(t) in the case where the modulation frequency ω_{b} is applied to the relaxing light 106b has a form in which the modulation frequency ωₐ in Expression (5) is replaced by the modulation frequency ω_{b}.

The probe light 110 output from the probe light optical system 109 is linearly-polarized. The polarization plane of the probe light 110 having passed through the measurement region 117a is subjected to paramagnetic Faraday rotation proportional to the spin polarization Sₓ^{a}(t) in the measurement region 117a. Then, the polarization plane of the probe light 110 having passed through the measurement region 117b is further subjected to paramagnetic Faraday rotation proportional to the spin polarization Sₓ^{b}(t). As a result, the probe light 110 having passed through the cell 101 is subjected to rotation of a polarization plane having a magnitude of an addition of the Faraday rotations from two places of the measurement regions 117a and 117b.

Then, the probe light 110 enters the polarization splitter 111 and is split into reflected light and transmitted light with the intensity in accordance with the angle of the polarization plane. The light having passed through the polarization splitter 111 is detected by the photodetector 112, and the light having been reflected from the polarization splitter 111 is detected by the photodetector 113. Then, the detected lights are output to the differential circuit 114 as detection signals. The detection signals are measured for a difference in light intensity by the differential circuit 114, and magnetic signals reflecting the magnetic field intensities in the measurement region 117a and 117b are output. The output signals are demodulated at frequencies in accordance with the modulation frequencies of the optical modulators 107 and 108 by the demodulators 115 and 116.

An output V(t) from the demodulator 115 in the case of being demodulated at an angular frequency ωₐ in the demodulator 115 is represented by the following expression (Expression (6)). Here, Vₐ represents a proportional constant from the magnitude of spin polarization such as the intensity and absorption coefficient of the probe light to the output of the circuit.

$$V ( t ) ≅ {V}_{a} \{ \frac{( ω - {Ω}_{0} ) sin ( ω t ) + ( \frac{1}{{T}_{2}} + \frac{{R}_{op}}{q} + \frac{{R}_{rel}}{2 q} ) cos ( ω t )}{{( \frac{1}{{T}_{2}} + \frac{{R}_{op}}{q} + \frac{{R}_{rel}}{2 q} )}^{2} + {( ω - {Ω}_{0} )}^{2}} - \frac{( ω + {Ω}_{0} ) sin ( ω t ) + ( \frac{1}{{T}_{2}} + \frac{{R}_{op}}{q} + \frac{{R}_{rel}}{2 q} ) cos ( ω t )}{{( \frac{1}{{T}_{2}} + \frac{{R}_{op}}{q} + \frac{{R}_{rel}}{2 q} )}^{2} + {( ω + {Ω}_{0} )}^{2}} \} \qquad ( 6 )$$

When the difference between the two modulation frequencies ωₐ and ω_{b} is sufficiently large as compared to the frequency of a magnetic field to be measured, the magnetic signal from the measurement region 117a and the magnetic signal from the measurement region 117b are sufficiently separated in a frequency region. Therefore, the magnetic signal from the measurement region 117a can be measured by performing demodulation at the same frequency as the modulation frequency of the optical modulator 107 in the demodulator 115. Further, the magnetic signal from the measurement region 117b can be measured by performing demodulation at the same frequency as the modulation frequency of the optical modulator 108 in the demodulator 116. With this, magnetic signals from spatially different places on an optical path of the probe light 110 can be separated and measured.

As described above, according to this embodiment, different modulations are performed with respect to relaxing lights that enter different positions in the cell, and hence magnetic information of the different positions can be transmitted with the probe light. With this, magnetic information of spatially different places on an optical path of one probe light can be separated and measured simultaneously.

A plurality of cells may be used instead of one cell. When one cell is used, a plurality of relaxing lights enter the cell. Further, when a plurality of cells are used, pump light and relaxing light enter each of the plurality of cells. Further, this embodiment is not limited to the case where a plurality of relaxing lights are modulated at different modulation frequencies, and also includes the case where the plurality of relaxing lights are modulated at different phases. When the plurality of relaxing lights are modulated at different phases, it is preferred that the modulation frequency be the same. However, the modulation frequency may be different as long as magnetic information of different positions can be discriminated.

In the second embodiment to the sixth embodiment, and a modified embodiment of the present invention, matters different from those of the first embodiment are now described, and the common matters are omitted.

### The Second Embodiment

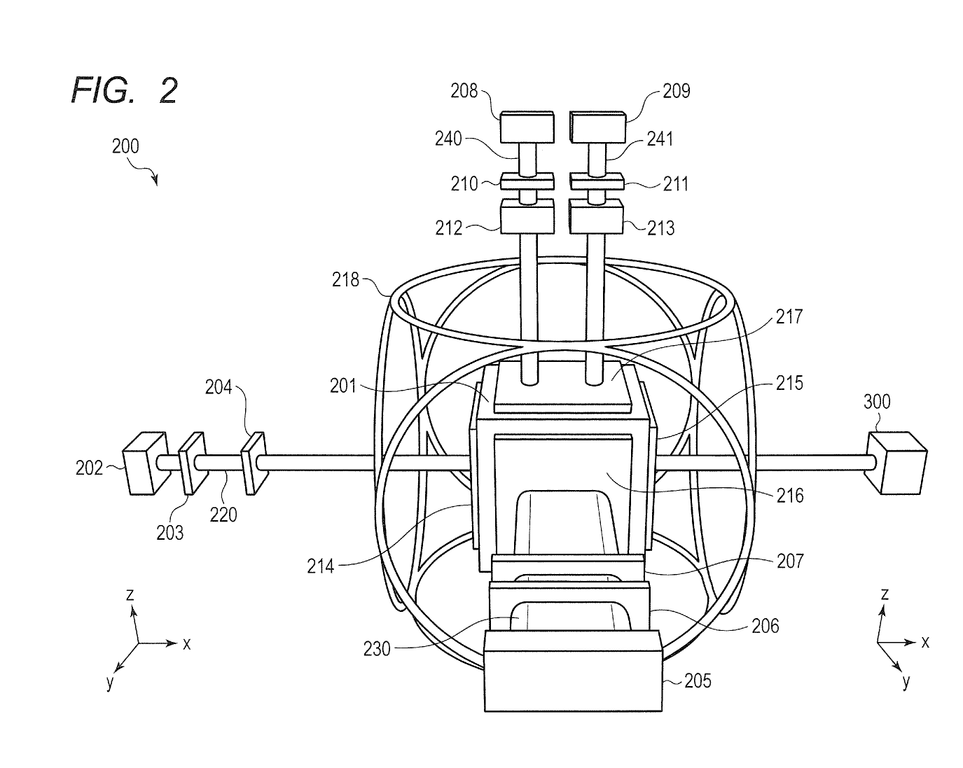

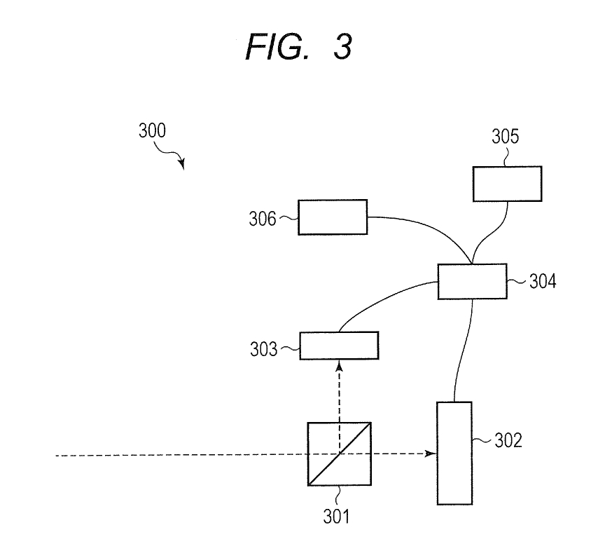

An optically pumped magnetometer and a magnetic sensing method according to the second embodiment of the present invention are described with reference to FIG. 2 and FIG. 3. The same components as those of the optically pumped magnetometer according to the first embodiment illustrated in FIG. 1 are denoted by the same names, and the descriptions thereof are omitted or simplified. The descriptions in each embodiment regarding the same components are mutually applicable to each embodiment within a range not contradicting a specific configuration of each embodiment.

FIG. 2 is a perspective view illustrating a schematic configuration of the optically pumped magnetometer according to this embodiment.

First, the schematic configuration of the optically pumped magnetometer according to this embodiment is described with reference to FIG. 2.

As illustrated in FIG. 2, an optically pumped magnetometer 200 according to this embodiment includes an isothermal insulating bath 201, a probe light source 202, a linear polarizer 203, a half wavelength plate 204, a pump light source 205, a linear polarizer 206, a quarter wavelength plate 207, relaxing light sources 208 and 209, linear polarizers 210 and 211, optical modulators 212 and 213, and a polarization measurement system 300.

In the isothermal insulating bath 201, a cell containing alkali metal atoms, e.g., potassium (K) atoms are arranged. Optical windows 214, 215, 216, and 217 configured to introduce probe light 220, pump light 230, and relaxing lights 240 and 241 into the isothermal insulating bath 201 are formed on wall surfaces of the isothermal insulating bath 201. A bias magnetic field adjusting coil 218 is arranged on the periphery of the isothermal insulating bath 201.

The probe light source 202 is configured to cause the probe light 220 having a linear polarization component to enter the cell in the isothermal insulating bath 201 through the linear polarizer 203, the half wavelength plate 204, and the optical window 214. The probe light 220 having passed through the cell enters the polarization measurement system 300 through the optical window 215. The above-mentioned probe light optical system is arranged so that the probe light 220 propagates through the cell in the isothermal insulating bath 201 along an x direction in a coordinate system illustrated in FIG. 2.

The pump light source 205 is configured to cause the pump light 230 to enter the cell in the isothermal insulating bath 201 through the quarter wavelength plate 207 and the optical window 216. The pump light 230 having a circular polarization component, which has entered the cell, intersects with the probe light 220 and the relaxing lights 240 and 241. The above-mentioned pump light optical system is arranged so that the pump light 230 propagates through the cell in the isothermal insulating bath 201 along −y direction (the direction opposite to the y direction) in the coordinate system illustrated in FIG. 2. The pump light 230 having been transmitted through the cell is optically terminated in the isothermal insulating bath 201. Alternatively, the pump light 230 may be terminated with an optical terminator or the like after being output from the isothermal insulating bath 201 through the optical window.

The relaxing light source 208 is configured to cause the relaxing light 240 to enter the cell in the isothermal insulating bath 201 through the linear polarizer 210, the optical modulator 212, and the optical window 217. The relaxing light source 209 is configured to cause the relaxing light 241 to enter the cell in the isothermal insulating bath 201 through the linear polarizer 211, the optical modulator 213 and the optical window 217.

With this, the relaxing lights 240 and 241 having a linear polarization component enter different positions in the cell of the isothermal insulating bath 201. The relaxing lights 240 and 241 having entered the cell in the isothermal insulating bath 201 intersect with the probe light 220 and the pump light 230 at different positions in the cell. The above-mentioned relaxing light optical system is arranged so that the relaxing lights 240 and 241 propagate through the cell along the −z direction in the coordinate system illustrated in FIG. 2.

The relaxing lights 240 and 241 having passed through the cell are optically terminated in the isothermal insulating bath 201. Alternatively, the relaxing lights 240 and 241 may be optically terminated with the optical terminator or the like after being output from the isothermal insulating bath 201 through the optical window.

The probe light 220 having entered the polarization measurement system 300 is measured for polarization thereof. FIG. 3 is a detailed diagram of the polarization measurement system 300. The probe light 220 is split into reflected light and transmitted light with the intensity in accordance with the angle of the polarization plane by a polarization splitter 301. Then, the transmitted light from the polarization splitter 301 enters a photodetector 302, and the reflected light from the polarization splitter 301 enters a photodetector 303. Demodulators 305 and 306 are connected to the photodetectors 302 and 303 through a differential circuit 304.

Next, each component of the optically pumped magnetometer 200 according to this embodiment is more specifically described.

[1] Isothermal Insulating Bath

A glass cell is installed in the isothermal insulating bath 201. The cell is an airtight structure formed of a transparent material, which transmits probe light and pump light, e.g., glass. Alkali metal atoms are sealed in the cell. As the alkali metal atoms that can be used for the cell herein, there are given potassium (K), rubidium (Rb), and cesium (Cs). The alkali metal atoms to be sealed in the cell is not necessarily required to be one kind, and may contain at least one kind of atoms selected from the group consisting of potassium, rubidium, and cesium.

Further, a buffer gas and a quencher gas are further sealed in the cell. As the buffer gas, there is given helium (He). Helium has an effect of suppressing the diffusion of a polarized alkali metal atom, and is effective for suppressing spin relaxation caused by the collision with the cell wall, maintaining a polarization ratio. Further, as the quencher gas, there is given nitrogen (N₂). Nitrogen serves to take energy out of the potassium atom in an excited state to suppress fluorescence, and is effective for enhancing the efficiency of optical pumping.

Of the alkali metal atoms, potassium has the smallest scattering cross-section with respect to spin polarization destruction caused by the collision between the potassium atoms and the collision between the potassium atom and the helium atom. Rubidium has the second smallest scattering cross-section with respect to spin polarization destruction, following the potassium atom. Therefore, as the alkali metal for constructing a magnetic sensor having a long relaxation time and a large magnetic signal response, the potassium is preferred.

Meanwhile, the rubidium and the cesium have a high vapor pressure under the same temperature as compared to that of the potassium. Therefore, the rubidium and the cesium have the advantage of being able to obtain the same atomic number density at a lower temperature as compared to the potassium. Therefore, from the viewpoint of constructing a sensor that is operated at a lower temperature, it is also effective to use rubidium or cesium.

Further, there may be arranged a structure, e.g., a plate, capable of physically separating the measurement regions in which the relaxing lights 240 and 241 and the probe light 220 intersect with each other in the cell so that spin polarization is not mixed through the diffusion of spin-polarized atoms and the spin exchange collision. It is preferred that this structure be formed of a transparent structure capable of transmitting the probe light, e.g., a glass plate, and holes for allowing the buffer gas to pass therethrough may be formed in portions except those through which the probe light passes.

At a time of measurement, in order to increase the density of the alkali metal atom in vapor state in the cell, the cell is heated to a temperature up to about 200° C. The isothermal insulating bath 201 serves to prevent the heat from escaping outside. The optical windows 214 and 215 are formed on an optical path of the probe light 220 in the isothermal insulating bath 201, the optical window 216 is formed on an optical path of the pump light 230, and the optical window 217 is formed on optical paths of the relaxing lights 240 and 241. Thus, those lights can pass through the isothermal insulating bath 201.

As a heating system for the cell in the isothermal insulating bath 201, there is given, for example, a system for causing heated inert gas to flow into the isothermal insulating bath 201 from outside, to thereby heat the cell. Alternatively, a system for causing a current to flow through a heater arranged in the isothermal insulating bath 201, to thereby heat the cell. In this case, in order to prevent a magnetic field caused by the heater current from influencing a measurement signal, it is effective to drive the heater with a current having a frequency that is twice as high as the modulation frequency of the pump light. Further, an optical heating system may be used, which causes a light-absorbing member arranged in or on the periphery of the cell to absorb light introduced from outside of the isothermal insulating bath 201, to thereby heat the cell.

[2] Bias Magnetic Field Adjusting Coil

As illustrated in FIG. 2, the bias magnetic field adjusting coil 218 is arranged on the periphery of the isothermal insulating bath 201. The bias magnetic field adjusting coil 218 is installed in a magnetic shield for reducing a magnetic field that enters from an external environment (not shown).

The bias magnetic field adjusting coil 218 is used for operating a magnetic field environment on the periphery of the cell in the isothermal insulating bath 201. As a specific example of the bias magnetic field adjusting coil 218, there is given, for example, triaxial Helmholtz coils. Specifically, the bias magnetic field adjusting coil 218 applies a bias magnetic field in a direction (y direction in FIG. 2) parallel to the pump light 230 so that the measurement frequency and the Larmor frequency are matched with each other to be resonated. Then, a magnetic field in a direction (z direction in FIG. 2) orthogonal to the probe light 220 and the pump light 230 is measured.

Further, the bias magnetic field adjusting coil 218 for applying a magnetic field in the other directions (x direction and z direction in FIG. 2) is used for canceling a residual magnetic field to form an environment in which no magnetic field is applied. Further, in order to correct a non-uniform magnetic field, a gradient correcting coil (shim coil) may be additionally installed.

[3] Probe Light Optical System

The probe light optical system includes the probe light source 202, the linear polarizer 203, and the half wavelength plate 204.

The wavelength of the probe light 220 output from the probe light source 202 takes dephasing of from several GHz to tens of GHz from the D1 transition resonance wavelength of the alkali metal atom so that a signal response becomes maximum. The value of dephasing for maximizing a signal response depends on the buffer gas pressure and temperature of the cell in the isothermal insulating bath 201. In order to stably keep the wavelength, the probe light source 202 may include a stabilization unit, e.g., an external resonator. The probe light 220 is formed into linearly-polarized light by the linear polarizer 203. Further, as a selection criterion of the wavelength, dephasing may be selected under conditions of maximizing a signal-noise ratio (S/N ratio). In the case of using any criterion, an optimum dephasing amount depends on the pump light intensity in the cell, and hence it is also effective to correct a dephasing amount by performing calibration periodically during measurement.

[4] Pump Light Optical System

As illustrated in FIG. 2, the pump light optical system includes the pump light source 205, the linear polarizer 206, and the quarter wavelength plate 207.

The wavelength of the pump light 230 output from the pump light source 205 is matched with the D1 transition resonance wavelength of the alkali metal atom. The pump light source 205 includes a light frequency stabilization unit configured to fix the wavelength of the pump light 230 to the D1 transition resonance wavelength of the alkali metal atom. The pump light 230 is formed into linearly-polarized light by the linear polarizer 206, and is converted into circularly-polarized light by the quarter wavelength plate 207. In this case, the pump light 230 may be converted into any of right circularly-polarized light and left circularly-polarized light.

The pump light 230 formed into circularly-polarized light enters the cell in the isothermal insulating bath 201 and polarizes an alkali metal atomic group on an optical path of the pump light 230 in the cell.

Further, as the pump light optical system, the following configuration can also be used. The intersection region between the probe light 220 and the relaxing light 240 and the intersection region between the probe light 220 and the relaxing light 241 are irradiated with pump lights from separate pump light sources to cause spin polarization.

[5] Relaxing Light Optical System

As illustrated in FIG. 2, the relaxing light optical system includes the relaxing light sources 208 and 209, the linear polarizers 210 and 211, and the optical modulators 212 and 213.

It is necessary that the wavelengths of the relaxing light 240 output from the relaxing light source 208 and the relaxing light 241 output from the relaxing light source 209 be matched with the D1 transition resonance wavelength of the alkali metal atom. Therefore, the relaxing light sources 208 and 209 include a light frequency stabilization unit configured to fix the wavelengths of the relaxing lights 240 and 241 to the D1 transition resonance wavelength of the alkali metal atom, for example, 770.1 nm in the case of the D1 transition resonance wavelength of the potassium atom. As the relaxing light, light from one light source may be split with a beam splitter or the like to be used. Further, the wavelength of the relaxing lights 240 and 241 may be fixed to the D2 transition resonance wavelength of the alkali metal atom, for example, 766.7 nm in the case of the D2 transition resonance wavelength of the potassium atom. Further, in the case where the relaxing light intensity is sufficient, the wavelength of the relaxing light may be detuned to some degree from the transition resonance wavelength.

The relaxing lights 240 and 241 are formed into linearly-polarized lights in the linear polarizers 210 and 211, respectively, and then are modulated by the optical modulators 212 and 213. The polarized lights of the relaxing lights 240 and 241 are preferably linearly-polarized lights so as to accelerate spin relaxation efficiently with relaxing light having a predetermined intensity.

The relaxing lights 240 and 241 enter the cell in the isothermal insulating bath 201 through the optical window 217 and relax the spin polarization of an alkali metal atomic group on optical paths of the relaxing lights 240 and 241 in the cell of the isothermal insulating bath 201. The relaxing lights 240 and 241 can simultaneously enter different portions of the cell. The relaxing lights 240 and 241 and the pump light 230 are not necessarily required to be orthogonal to each other. It is sufficient that the relaxing lights 240 and 241 be transmitted through the intersection region between the probe light 220 and the pump light 230, and can be caused to enter the intersection region at any angle with respect to the pump light 230. Further, the following may be possible. The pump light 230 that is transmitted through the quarter wavelength plate 207 to become circularly-polarized light may be superposed with a half mirror or the like to enter the cell from the same z direction.

The relaxing lights 240 and 241 having been transmitted through the cell in the isothermal insulating bath 201 is optically terminated in the isothermal insulating bath 201. Alternatively, the relaxing lights 240 and 241 may be optically terminated after being output from the isothermal insulating bath 201 through the optical window.

Three or more relaxing lights may be caused to simultaneously enter a plurality of portions through use of three or more relaxing light sources. In this case, magnetic information of three or more difference places can be measured simultaneously.

The relaxing lights 240 and 241 are modulated by the optical modulators 212 and 213. The longitudinal relaxation time T₁ of spin polarization in the presence of the relaxing light is about 1 ms. It is not efficient that the relaxing light is radiated for a period of time longer than the longitudinal relaxation time T₁ because a change in spin polarization becomes small. Therefore, the modulation frequency is preferably equal to or higher than 100 Hz, and more preferably equal to or higher than 1 kHz.

Further, as indicated by a coefficient of the second term in Expression (5):

$$\frac{{sR}_{op} {R}_{rel} {Ω}_{1}}{4 q {ω}_{a} ( \frac{4 q}{{T}_{1}} + 4 {R}_{op} + 2 {R}_{rel} )}$$

a response to a magnetic signal after modulation is inversely proportional to the modulation frequency ωₐ. This shows that, when the relaxing lights 240 and 241 are modulated at an extremely high frequency, the spin polarization cannot follow the modulation, thus the signal response becomes weak.

As fundamental noises of an atomic magnetic sensor, there exist a spin projection noise and a photon shot noise, and the levels of those noises remain unchanged even after modulation is applied. Under typical experimental conditions (temperature: 180° C., probe light wavelength: 770.1 nm, probe light power: 0.1 mW, probe light path length: 5 cm, pump light intensity: 0.2 mW/cm²), the photon shot noise becomes dominant. When a photon shot noise is calculated from a probe light power, the modulation frequency that becomes 10 fTᵣₘₛ/Hz^{1/2} in terms of a magnetic field noise becomes about 5 kHz. Therefore, it is preferred that the modulation frequency be equal to or less than 5 kHz.

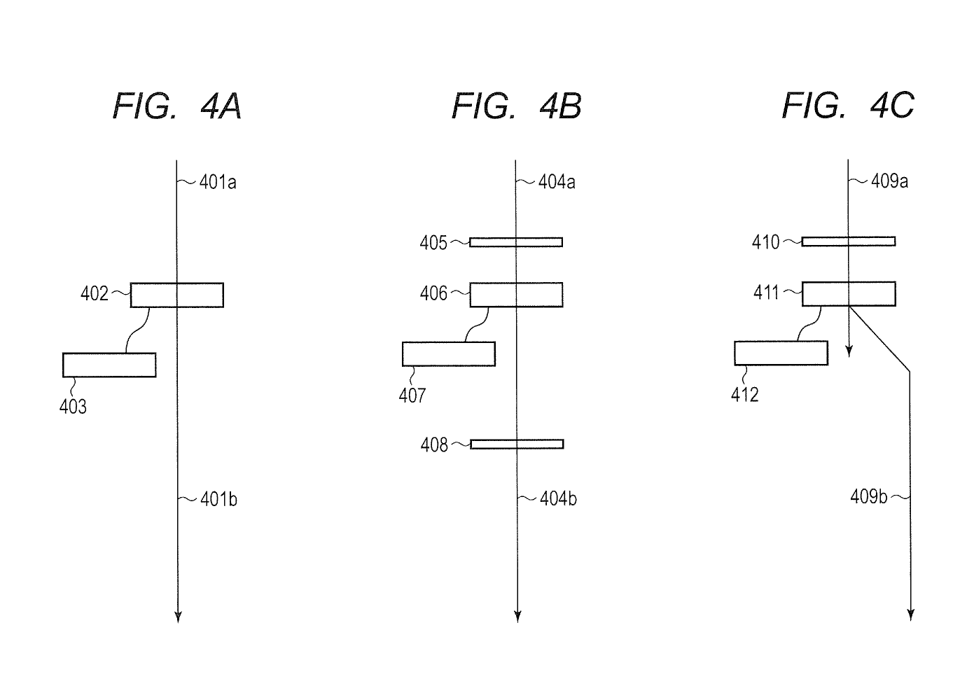

As the modulation system in the optical modulators 212 and 213, there are given, for example, relaxing light intensity modulation, relaxing light wavelength modulation, phase modulation, and pulse width (duty ratio) modulation. The specific configuration of the optical modulators 212 and 213 is described below with reference to FIG. 4A to FIG. 4C.

[5.1] Relaxing Light Intensity Modulation

As an example of the relaxing light intensity modulation, there is given a method using an optical chopper. The optical chopper is configured to block light periodically, and the intensity of light having passed through the optical chopper is modulated with a rectangular wave. That is, as illustrated in FIG. 4A, by causing relaxing light 401a to enter the optical chopper 402, relaxing light 401b having a light intensity modulated with a rectangular wave shape can be obtained. The modulation frequency of the optical chopper 402 can be controlled by a signal generator 403 configured to control the optical chopper 402.

As another example of the relaxing light intensity modulation, there is given a method using an electrooptical element. The electrooptical element is configured to change the phase and polarization state of light through use of a change in birefringence of a crystal caused by an electrooptical effect. As illustrated in FIG. 4B, relaxing light 404a is caused to enter a half wavelength plate 405, and the polarized light of the relaxing light 404a is tilted by 45° with respect to the application direction of an electric field of the electrooptical element 406. Then, the relaxing light 404a having passed through the half wavelength plate 405 is caused to pass through the electrooptical element 406 so that the phase difference of the polarized light thereof is modulated. This is the same as changing the circular polarization degree of light periodically. When the light having the circular polarization degree modulated passes through the linear polarizer 408, a polarization component in a direction different from a transmission axis direction of the linear polarizer 408 is not transmitted through the linear polarizer 408, and hence the modulation of the circular polarization degree can be converted into intensity modulation. That is, relaxing light 404b having light intensity modulated can be obtained. The modulation frequency of the electrooptical element 406 can be controlled by a signal generator 407 configured to control an electric field to be applied to the electrooptical element 406.

Besides the above-mentioned methods, the relaxing light intensity modulation may be direct intensity modulation involving applying modulation to a drive current itself of a laser light source such as a DFB laser or a DBR laser. Further, an electric optical modulator such as an electric field absorption type modulator may be used.

[5.2] Relaxing Light Wavelength Modulation

As an example of a method of changing the wavelength of the relaxing light, there is given a method using an acoustic optical element. As illustrated in FIG. 4C, when relaxing light 409a is caused to enter the acoustic optical element 411, there is an optimum polarization angle, and hence it is desired that the polarization angle be adjusted by a half wavelength plate 410. When an electric signal is applied to the acoustic optical element 411 by an RF generator 412, the relaxing light 409a is diffracted to some orders, and the light frequency thereof is changed. When the light frequency of the relaxing light 409a before entering the acoustic optical element 411 is defined as ω₀, and the frequency of the electric signal applied by the RF generator 412 is defined as ω_{RF}, the acoustic optical element 411 spatially separates the relaxing light 409a into N-order diffracted light having a light frequency of ω₀+Nω_{RF}. In this case, N represents any integer. With this, relaxing light 409b having a modulated wavelength can be obtained. A light frequency change amount of first-order diffracted light is generally from about tens of MHz to hundreds of MHz. In order to increase the intensity of a modulation signal, it is appropriate that the light frequency change amount be as large as a half width at half maximum of the absorption line width. In the case of a glass cell in which about 1 [amg] of helium buffer gas is sealed, the light frequency change amount is preferably several GHz. Therefore, it is necessary to select high-order diffracted light. [amg] as used here refers to a magnitude of an atmospheric pressure measured at 0° C.

Besides the above-mentioned method, the relaxing light wavelength modulation can also be performed by electrical wavelength tuning of a laser light source such as a DFB laser and a DBR laser.

[6] Polarization Measurement System

As illustrated in FIG. 3, the polarization measurement system includes the polarizer splitter 301, the photodetectors 302 and 303, the differential circuit 304, and the demodulators 305 and 306.

The probe light 220 that enters the polarization splitter 301 is split into transmitted light and reflected light in accordance with a polarization angle θ. When a ratio is taken with light power, an intensity ratio between the transmitted light and the reflected light is cos² θ:sin² θ. This is based on the polarization state in which the entire incident light to the polarization splitter 301 is transmitted therethrough and enters the photodetector 302, that is, the case where θ=0°. In this case, light at θ=90° is totally reflected to enter the photodetector 303.

The power intensities of light split into two lights are measured by the photodetectors 302 and 303, respectively, and the difference thereof is output from the differential circuit 304. When the polarized light of the probe light 220 at a time when a magnetic field to be measured is not present is adjusted to θ=45°, lights having the same light power enter the photodetectors 302 and 303 when the magnetic field to be measured is not present, and the output from the differential circuit 304 becomes 0.

Meanwhile, when the magnetic field to be measured is present, rotation of a polarization plane occurs in accordance with the magnitude of the magnetic field to be measured, and lights having different light powers enter the photodetectors 302 and 303, with the result that the difference therebetween, which is not 0, is output from the differential circuit 304. That is, the output from the differential circuit 304 in this case is a signal proportional to the rotation angle of the polarization plane of the probe light, which reflects a magnetic field intensity in each measurement.

The output signal from the differential circuit 304 is input to and demodulated by the demodulators 305 and 306. As the demodulator, there is given, for example, a lock-in amplifier. In this case, by demodulating the output signal at the same frequency as the demodulation frequency of the optical modulator 212 in the demodulator 305, a magnetic signal in the intersection region between the probe light 220 and the relaxing light 240 can be taken out. Further, by demodulating the output signal at the same frequency as the modulation frequency of the optical modulator 213 in the demodulator 306, a magnetic signal in the intersection region between the probe light 220 and the relaxing light 241 can be taken out.

Here, an example in which magnetic signals in different regions are obtained through use of the two demodulators 305 and 306 is described. However, the method of obtaining magnetic signals from different regions is not limited thereto. For example, the output of the differential circuit 304 may be taken as a digital signal into an A/D converter instead of providing a plurality of demodulators, and then the digital signal may be subjected to digital signal processing. Regarding the digital signal thus taken out, data on a predetermined frequency width in accordance with each modulation frequency is filtered in a frequency region, and thus magnetic signals in the respective intersection regions can be separated.

Further, in order to increase separation accuracy of the magnetic signals between the intersection regions, a thin plate formed of a conductor, e.g., aluminum, may be arranged between the sensor and the signal source. For example, when modulation frequencies of the relaxing lights 240 and 241 are defined as f_{b}[Hz] and f_{c}[Hz] (f_{b}<f_{c}), respectively, it is necessary that the frequency band capable of being measured in each measurement region be limited to a half (f_{c}−f_{b})/2 [Hz] or less of a modulation frequency difference. For example, a signal frequency to be measured, which is a frequency of a signal to be measured with the relaxing light 240, is defined as fₓ[Hz], and a signal frequency to be measured, which is a frequency of a signal to be measured with the relaxing light 241, is defined as f_{y}[Hz]. In this case, the frequency spectrum of the output from the differential circuit 304 has four peaks: f_{b}−fₓ[Hz], f_{b}+fₓ[Hz], f_{c}−f_{y}[Hz], and f_{c}+f_{y}[Hz]. When the output from the differential circuit 304 is separated at the frequency (f_{b}+f_{c})/2 [Hz] and demodulated separately, signals having frequencies to be measured fₓ[Hz] and f_{y}[Hz] can be taken out respectively. However, when the signal frequency to be measured f_{y} is larger than the half of the modulation frequency difference (f_{c}−f_{b})/2 [Hz], (f_{b}+f_{c})/2>f_{c}−f_{y} is obtained and this signal with the frequency f_{c}−f_{y} goes into demodulator 305 and demodulated with f_{b}, resulting the demodulated signal at f_{c}-f_{y}-f_{b}[Hz]. Therefore, in the case where the output from the differential circuit 304 is demodulated by the demodulators 305 and 306, a signal having a frequency f_{c}-f_{b}-f_{y}[Hz] is output in addition to the signal having the frequency fₓ[Hz], which is the signal f_{b}+fₓ demodulated with f_{b}. This means that a signal from the intersection region with the relaxing light 241 is mixed, as a noise, with the outputs from the demodulators 305 and 306, and is confused with a signal to be measured from the intersection region with the relaxing light 240. In order to prevent this mixing, a thin plate formed of a conductor, e.g., aluminum, is arranged on the periphery of the isothermal insulating bath 201 to block a magnetic signal having a frequency of (f_{c}−f_{b})/2 [Hz] or more. As a result, a high-frequency magnetic signal is blocked, and the separation accuracy of magnetic signals between the intersection regions is increased. The blocking effect of the conductor with respect to a magnetic field that changes with time becomes higher as the frequency is higher, and hence is a low-pas filter characteristic. As a guideline of the thickness of the conductor plate, the thickness can be set to about a skin depth with respect to an AC magnetic field at a cut-off frequency. In the case where the frequency difference of the modulation frequencies is 1 kHz, a magnetic signal of equal to or higher than 500 Hz can be attenuated to 1/e (≈0.37) by arranging an aluminum plate having a thickness of 3 mm in consideration of the RF blocking effect. In this case, the configuration in which a biomagnetic signal of equal to or less than 100 Hz is hardly attenuated can be achieved.

As described above, according to this embodiment, the modulation frequencies of the relaxing lights that enter different positions in the cell can be changed, and hence magnetic information of the different positions can be transmitted with the probe light. With this, magnetic information of spatially different places can be separated and measured simultaneously with one probe light.

### The Third Embodiment

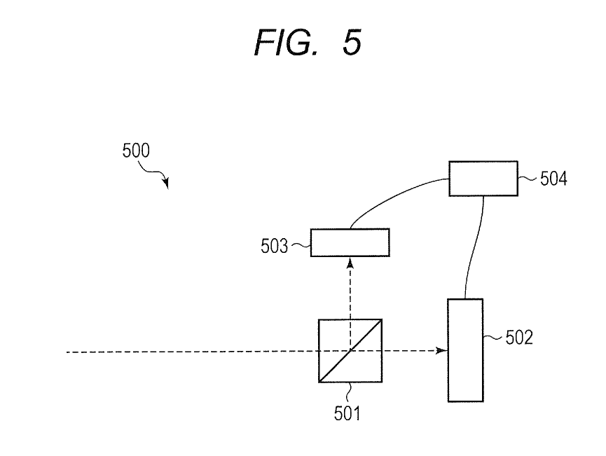

An optically pumped magnetometer and a magnetic sensing method according to the third embodiment of the present invention are described. The configuration and action of the optically pumped magnetometer according to this embodiment are the same as those of the optically pumped magnetometer according to the second embodiment illustrated in FIG. 2 in the isothermal insulating bath, the bias magnetic field adjusting coil, the probe light optical system, and the pump light optical system. Further, the configuration of the relaxing light optical system is the same as that of the second embodiment, but is different therefrom in the manner of applying modulation in the optical modulators 212 and 213. The detailed configuration of a polarization measurement system 500 includes a polarization splitter 501, photodetectors 502 and 503, and a differential circuit 504, as illustrated in FIG. 5.

In the optically pumped magnetometer according to this embodiment, the modulation frequencies applied to the relaxing lights 240 and 241 are the same, but the phases of modulation are different from each other. The descriptions of the same portions as those of the second embodiment are omitted or simplified, and portions specific to this embodiment are mainly described below.

In this embodiment, frequencies f_{mod} of modulation to be applied to the relaxing lights 240 and 241 by the optical modulators 212 and 213 are the same, and the phases of the modulation are different from each other. The modulation frequency f_{mod} is selected so that the relationship between the modulation frequency f_{mod} and the relaxing time T₂ of spin polarization of the alkali metal atom becomes T₂≦1/(2πf_{mod})=T_{mod}. As an example, there is given a cell containing alkali metal atoms in which the relating time T₂ becomes 1 ms when the modulation frequency f_{mod} is 160 Hz. As described in the second embodiment, typically, the longitudinal relaxation time T₁ of spin polarization in the presence of the relaxing light is about 1 ms, and this longitudinal relaxation is dominant. The longitudinal relaxation time T₁ can be adjusted to some degree by changing the relaxing light intensity.

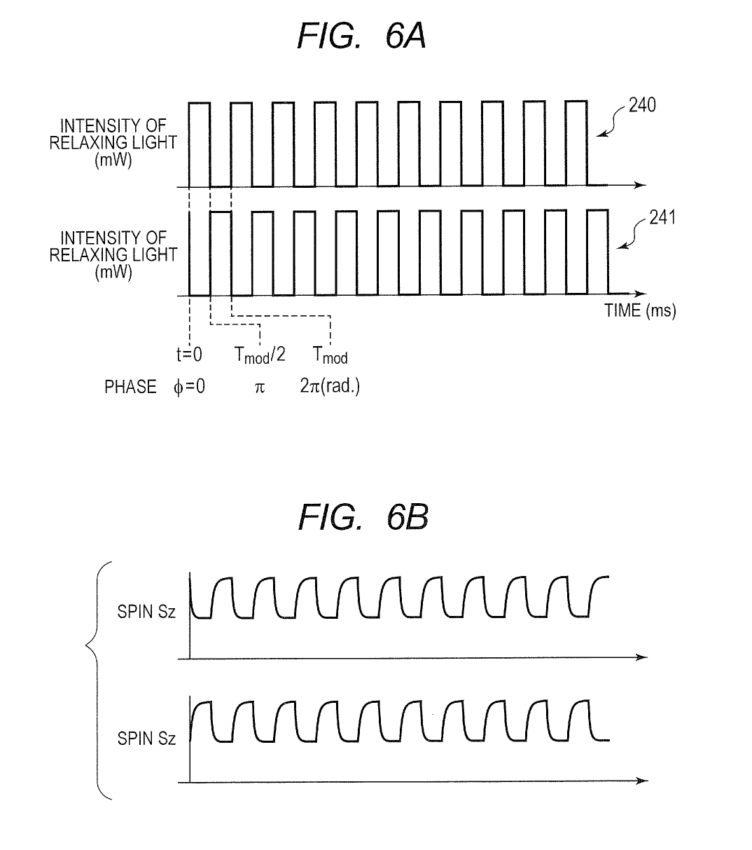

The state of the intensity modulation with different phases is illustrated in FIG. 6A. When measurement time t=0, the phase φ=0 is defined. The light intensity of the relaxing light 240 is large within a range of the phase φ of from 0 to π, and the light intensity thereof is 0 within a range of the phase φ of from π to 2π. Further, the light intensity of the relaxing light 241 is 0 within a range of the phase φ of from 0 to π, and the light intensity thereof is large within a range of the phase φ of from π to 2π.

Thus, the relaxing light 240 and 241 modulated at the same modulation frequency and different phases are radiated to different regions on an optical path of the probe light 220. As a result, a component S_{z} of a spin in the pump light direction in the intersection regions between the relaxing light 240 and the probe light 220 and between the relaxing light 241 and the probe light 220 is expressed by a time waveform illustrated in FIG. 6B. That is, the region irradiated with the relaxing light 240 and the region irradiated with the relaxing light 241 are subjected to periodic modulations complementary to each other. Due to the influence of the relaxing time, the time waveform of a magnitude of each spin S_{z} becomes a dull shape that is limited by a finite rising and falling time with respect to the rectangular waves of the relaxing lights 240 and 241.

The spin S_{z} is further rotated in accordance with a magnetic field to be measured to generate a component Sₓ of a spin in the probe light direction. Therefore, a signal subjected to modulation is superposed on a signal read with the probe light 220. The output obtained from the probe light 220 through the polarization splitter 501, the photodetectors 502 and 503, and the differential circuit 504 is a signal proportional to the rotation angle of the polarization plane of the probe light 220 in the same manner as in the second embodiment.

The output from the differential circuit 504 is subjected to the following signal processing, thereby being capable of separating a magnetic field signal in each measurement region.

First, the output from the differential circuit 504 is digitized with an A/D converter (not shown) as a time-series signal. The digital data is classified into two pieces of time-series data with reference to the phase in the modulation frequency serving as a reference. In each piece of the time-series data, a missing point of the data is interpolated with data before and after the time-series data. When sampling theorem is considered, it is ensured that the signal can be reproduced by the interpolation as long as the signal band is limited to a frequency lower than a half of the modulation frequency. Actually, sampling data on a plurality of continuous points, which takes the phase conditions into consideration, can be used, and hence the signal can be reproduced accurately by smoother interpolation.

In the second embodiment, modulation frequencies of signals are caused to carry spatial information that the signals are from different places on an optical path of one probe light 220. However, in this embodiment, the phases at which the signals are modulated are caused to carry the spatial information. As such method for modulation, the modulation of a relaxing light wavelength described in the second embodiment is also effective.

In this embodiment, an example in which two relaxing lights are used for one probe light is described, but the number of the relaxing lights can also be increased to three or four. In the case where the measurements at three places are multiplexed through use of three relaxing lights, the measurements can be multiplexed by dividing the phase into three ranges of from 0 to 2π/3, from 2π/3 to 4π/3, and from 4π/3 to 2π. Further, in the case where the measurements at four places are multiplexed through use of four relaxing lights, the measurements can be multiplexed by dividing the phase for each π/2.

Thus, according to this embodiment, the relaxing lights that enter different positions in the cell are modulated at the same modulation frequency and different phases, and hence the magnetic information of each of the different positions can be transmitted with the probe light. With this, the magnetic signals in spatially different places can be separated and measured simultaneously using one probe light.

### The Fourth Embodiment

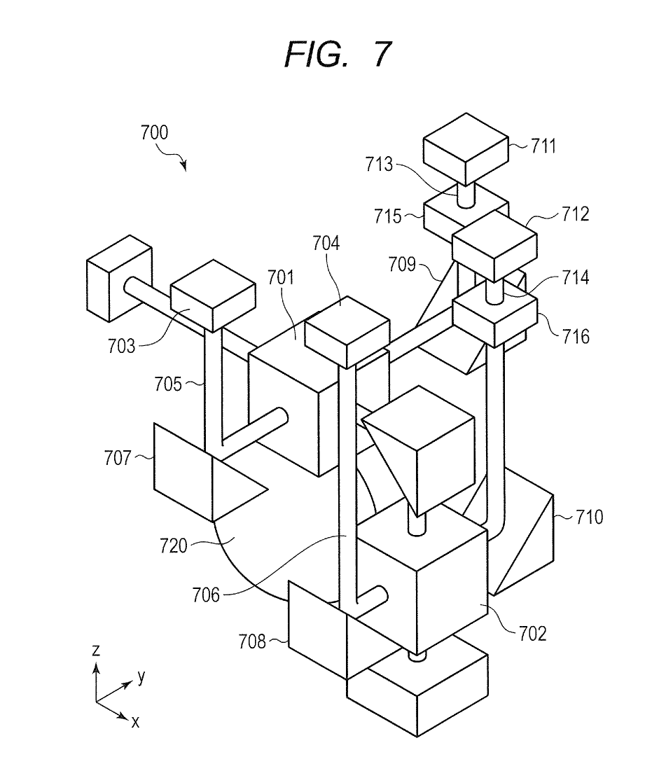

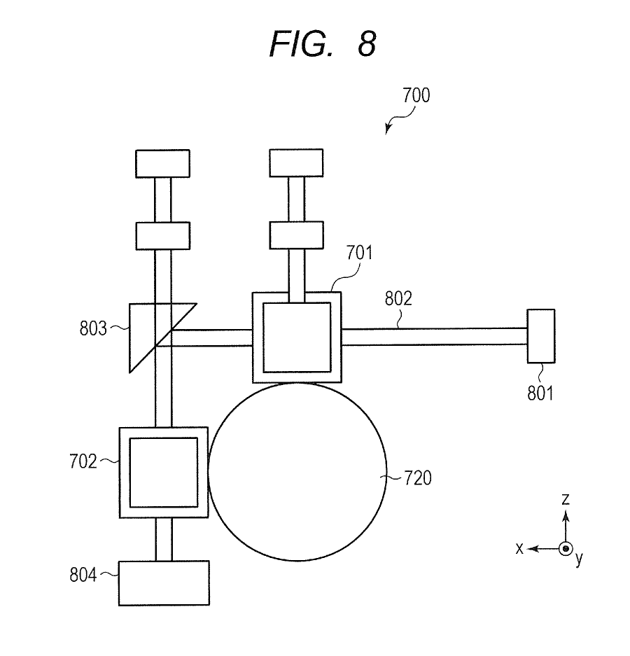

An optically pumped magnetometer and a magnetic sensing method according to the fourth embodiment of the present invention are described with reference to FIG. 7 and FIG. 8.

FIG. 7 is a perspective view illustrating a schematic configuration of the optically pumped magnetometer according to this embodiment. FIG. 8 is a schematic projective view along a surface parallel to an x-z plane in a coordinate system of FIG. 7.

First, the schematic configuration of the optically pumped magnetometer according to this embodiment is described with reference to FIG. 7 and FIG. 8.

As illustrated in FIG. 7, the optically pumped magnetometer 700 according to this embodiment includes isothermal insulating baths 701 and 702 each containing a cell, pump light sources 703 and 704, mirrors 707 and 708, relaxing light sources 711 and 712, optical modulators 715 and 716, and mirrors 709 and 710. Further, as illustrated in FIG. 7 and FIG. 8, the optical pumped magnetometer 700 includes a probe light optical system 801, a mirror 803, and a polarization measurement system 804. In FIG. 7 and FIG. 8, a spherical body drawn adjacently to the isothermal insulating baths 701 and 702 is defined as a measuring object 720.

An optical system of the optically pumped magnetometer 700 according to this embodiment is arranged so that probe light 802 emitted from a light source of the probe light optical system 801, pump lights 705 and 706 emitted from the pump light sources 703 and 704, and relaxing lights 713 and 714 emitted from the relaxing light sources 711 and 712 propagate through optical paths described below, respectively.

As illustrated in FIG. 8, the probe light 802 emitted from the light source of the probe light optical system 801 enters the isothermal insulating bath 701. Then, the probe light 802 propagates along an x direction through a first cell (not shown), in which the first alkali metal atoms are sealed, arranged in the isothermal insulating bath 701, and is output from the isothermal insulating bath 701. The probe light 802 output from the isothermal insulating bath 701 is bent by 90° by the mirror 803 to enter the isothermal insulating bath 702. Then, the probe light 802 propagates along the −z direction through a second cell (not shown), in which the second alkali metal atoms are sealed, arranged in the isothermal insulating bath 702, and is output from the isothermal insulating bath 702. The probe light 802 output from the isothermal insulating bath 702 enters the polarization measurement system 804.

As illustrated in FIG. 7, the pump light 705 emitted from the pump light source 703 enters the isothermal insulating bath 701 through the mirror 707 and propagates along a y direction through the first cell. The pump light 706 emitted from the pump light source 704 enters the isothermal insulating bath 702 through the mirror 708 and propagates along the y direction through the second cell. The pump lights 705 and 706 polarize an alkali metal atomic group in the cells with circular polarization components thereof. Further, the relaxing light 713 emitted from the relaxing light source 711 enters the isothermal insulating bath 701 through the optical modulator 715 and the mirror 709 and propagates along a −y direction through the first cell. Then, in the first cell, the probe light 802, the pump light 705, and the relaxing light 713 intersect with each other. The relaxing light 714 emitted from the relaxing light source 712 enters the isothermal insulating bath 702 through the optical modulator 716 and the mirror 710 and propagates along the −y direction through the second cell. Then, in the second cell, the probe light 802, the pump light 706, and the relaxing light 714 intersect with each other.

Next, regarding components of the optically pumped magnetometer according to this embodiment, points different from those of the embodiments described above are described more specifically. Portions that are not particularly described below are the same as those of the embodiments described above.

[1] Isothermal Insulating Bath

The isothermal insulating baths 701 and 702 each contain a cell (not shown) in which alkali metal atoms are sealed. The isothermal insulating baths 701 and 702 each include a heating unit so as to heat the cell at a temperature of about 180° C. Further, the isothermal insulating baths 701 and 702 each include a unit configured to transmit light to the cell in the isothermal insulating bath and take the light out of the cell, e.g., an optical window. Further, the bias magnetic field adjusting coil and the gradient correcting coil (not shown) as described in the second embodiment are arranged on each periphery of the isothermal insulating baths 701 and 702.

In the isothermal insulating baths 701 and 702, in order to uniformize the signal response characteristics of the cells contained in the isothermal insulating baths 701 and 702, the buffer gas pressures in the two cells are set to the same pressure to the extent possible, and the pressure difference is preferably set to within 0.1 [amg]. Further, the temperatures in the isothermal insulating baths 701 and 702 are also set to the same temperature to the extent possible, and the temperature difference is preferably set to within 0.1° C.

FIG. 7 and FIG. 8 are each an illustration of the case including the two isothermal insulating baths 701 and 702 each containing a cell. However, the number of the isothermal insulating baths each containing a cell is not limited to two, and the number of the isothermal insulating baths may also be increased as necessary. Further, each cell is not necessarily required to be arranged in separate isothermal insulating baths, and a plurality of cells may be arranged in a common large isothermal insulating bath.

The arrangement of the plurality of isothermal insulating baths 701 and 702 can be appropriately varied in accordance with the shape and the like of the measuring object 720. For example, in the example of FIG. 7 and FIG. 8, the isothermal insulating baths 701 and 702 are arranged so that the optical path of the probe light 802 that passes through the isothermal insulating bath 701 and the optical path of the probe light 802 that passes through the isothermal insulating bath 702 are orthogonal to each other. However, those optical paths are not necessarily required to be orthogonal to each other.

[2] Pump Light Optical System

The pump light optical system includes the pump light sources 703 and 704, and the mirrors 707 and 708.

The pump light sources 703 and 704 each include a light frequency stabilization unit configured to fix the wavelength of output light thereof to the D1 transition resonance wavelength of the alkali metal atom and a circular polarizer configured to circularly polarize the polarized light of the output light. The pump lights 705 and 706 polarize an alkali metal atomic group of the cells with the circular polarization component.

[3] Relaxing Light Optical System

The relaxing light optical system includes the relaxing light sources 711 and 712, the optical modulators 715 and 716, and the mirrors 709 and 710.

The relaxing light sources 711 and 712 each include a light frequency stabilization unit configured to fix the wavelength of output light thereof to the D1 transition resonance wavelength or the D2 transition resonance wavelength of the alkali metal atom, and a linear polarizer configured to linearly polarize the polarized light of the output light.

The relaxing light 713 output from the relaxing light source 711 and the relaxing light 714 output from the relaxing light source 712 are modulated at different modulation frequencies in the optical modulators 715 and 716. As the modulation method, for example, the method described in the second embodiment can be applied. Alternatively, the relaxing lights 713 and 714 are modulated at the same modulation frequency and different phases by the method described in the third embodiment in the optical modulators 715 and 716.

Further, it is not necessary that the pump light 705 and the relaxing light 713, and the pump light 706 and the relaxing light 714 respectively enter the cells in parallel with each other. It is sufficient that the relaxing light 713 be radiated to the intersection region between the probe light 802 and the pump light 705, and the relaxing light 714 be radiated to the intersection region between the probe light 802 and the pump light 706.

[4] Probe Light Optical System

The probe light optical system includes the probe light optical system 801, and the mirror 803.

The probe light 802 output from the probe light optical system 801 is linearly-polarized. The probe light 802 enters the isothermal insulating bath 701 and enters the cell in the isothermal insulating bath 701. The probe light 802 having entered the cell is subjected to Faraday rotation proportional to the magnetic field to be measured by the alkali metal atomic group in the cell.

The probe light 802 output from the isothermal insulating bath 701 is guided by the mirror 803 so as to be transmitted through the optical window to enter the isothermal insulating bath 702 and the cell in the isothermal insulating bath 702. The probe light 802 having entered the cell is further subjected to Faraday rotation proportional to the magnetic field to be measured by the alkali metal atomic group in the cell.

It is sufficient that a light guiding unit between the isothermal insulating bath 701 and the isothermal insulating bath 702 guide the probe light 802 so that the probe light 802 enters the isothermal insulating bath 702 through the optical window while keeping polarization of the probe light 802, and it is not necessarily required to use the mirror 803. For example, the probe light 802 may be guided through use of refraction caused by a prism or the like or may be guided through use an optical waveguide such as a polarization plane storing optical fiber instead of the mirror 803.

[5] Polarization Measurement System

The probe light 802 having been transmitted through the cell in the isothermal insulating bath 702 enters the polarization measurement system 804. The polarization measurement system 804 can be configured in the same manner as that of the polarization measurement system described in the second or third embodiment. With this, a magnetic signal in the intersection region of the probe light 802, the pump light 705, and the relaxing light 713, and a magnetic signal in the intersection region of the probe light 802, the pump light 706, and the relaxing light 714 can be taken out.

As described above, according to this embodiment, pump lights that enter different positions in the cell are modulated differently, and hence the magnetic information of each of the different positions can be transmitted with the probe light. With this, magnetic information of spatially different places can be separated and measured simultaneously with one probe light. Further, the magnetic information of different positions is measured through use of a plurality of cells, and hence the degree of freedom of setting of measurement positions can be enhanced.

### The Fifth Embodiment

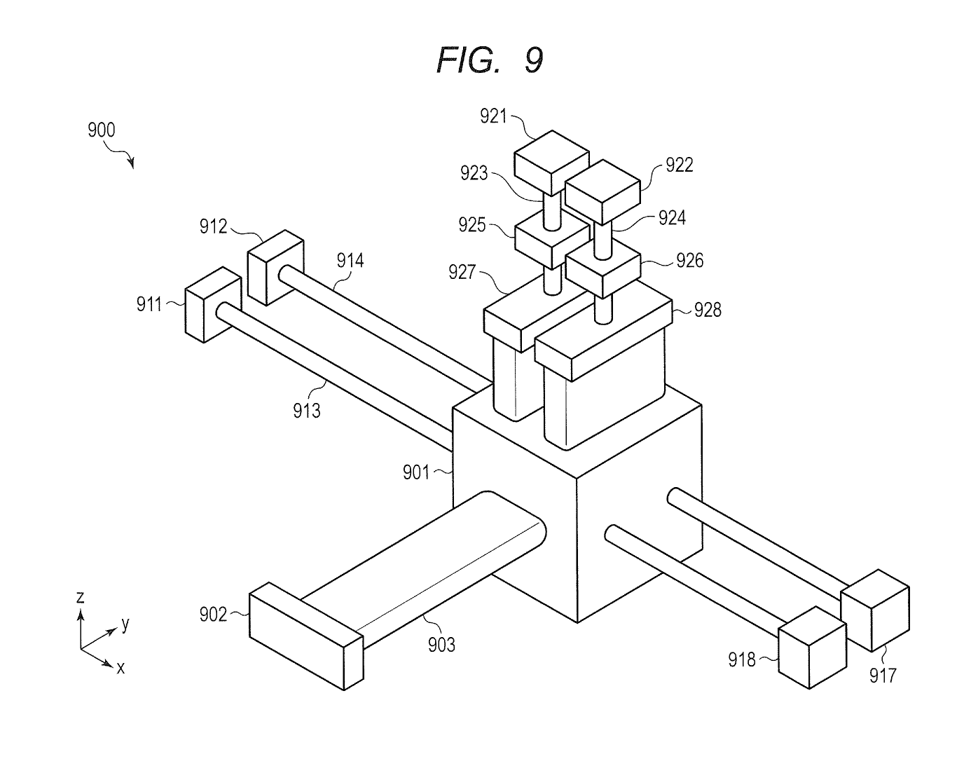

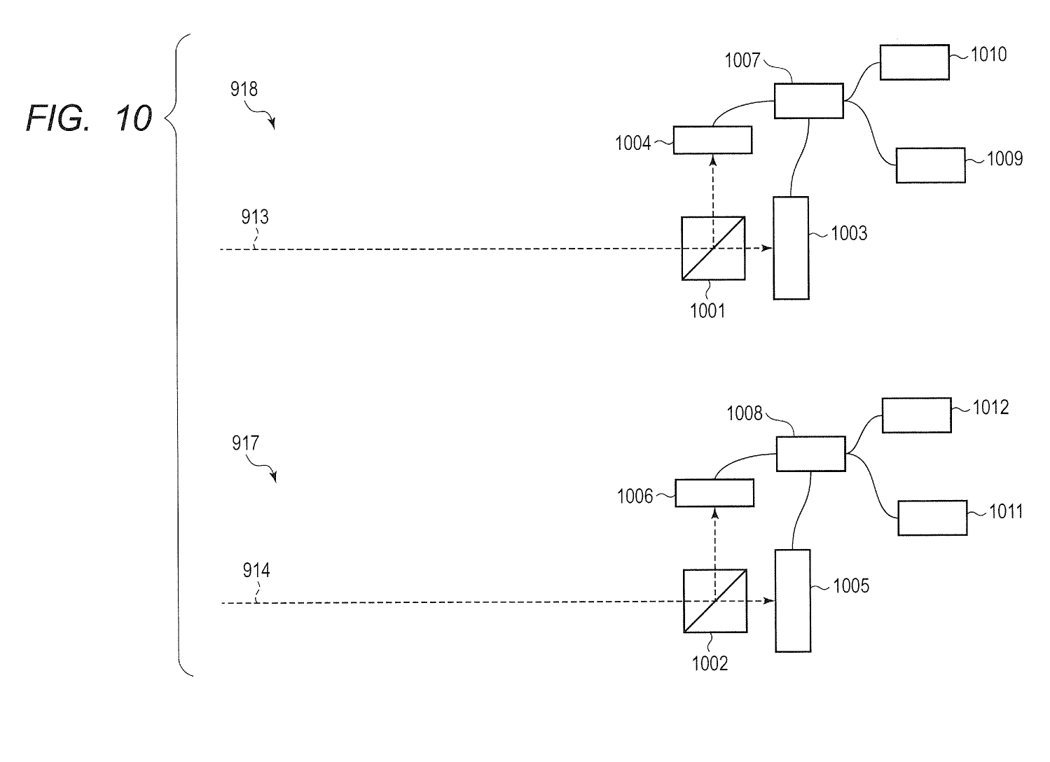

An optically pumped magnetometer and a magnetic sensing method according to the fifth embodiment of the present invention are described with reference to FIG. 9 and FIG. 10. In this embodiment, a combination of a plurality of kinds of alkali metal atoms is used, and for example, a combination of potassium and rubidium are used. Further, the combination of the plurality of kinds of alkali metal atoms may be a combination of potassium and cesium, or a combination of rubidium and cesium.

FIG. 9 is a perspective view illustrating a schematic configuration of the optically pumped magnetometer according to this embodiment.

As illustrated in FIG. 9, the optically pumped magnetometer 900 according to this embodiment includes an isothermal insulating bath 901, a pump light source 902, probe light sources 911 and 912, polarization measurement systems 917 and 918, relaxing light optical systems 912 and 922, optical modulators 925 and 926, and relaxing light expanding systems 927 and 928.

In the isothermal insulating bath 901, a cell containing potassium atoms and rubidium atoms is arranged. A bias magnetic field adjusting coil (not shown) is arranged on the periphery of the isothermal insulating bath 901.

The probe light source 911 is configured to cause probe light 913 having a linear polarization component to enter the cell in the isothermal insulating bath 901. The probe light 913 having passed through the cell enters the polarization measurement system 918 and the polarization thereof is measured.

The probe light source 912 is configured to cause probe light 914 having a linear polarization component to enter the cell in the isothermal insulating bath 901. The probe light 914 having passed through the cell enters the polarization measurement system 917, and the polarization thereof is measured.

The probe light optical system described above is arranged so that the probe lights 913 and 914 propagate through the cell in the isothermal insulating bath 901 along an x direction in a coordinate system illustrated in FIG. 9.

The pump light source 902 is arranged so that the pump light 903 having a circular polarization component propagates through the cell in the isothermal insulating bath 901 along a y direction in the coordinate system illustrated in FIG. 9.

The relaxing light source 921 is configured to cause relaxing light 923 having a linear polarization component to enter the cell in the isothermal insulating bath 901 through the optical modulator 925 and the relaxing light expanding system 927. The relaxing light 923 having entered the cell intersects with the probe lights 913 and 914 and the pump light 903.

The relaxing light source 922 is configured to cause relaxing light 924 to enter the cell in the isothermal insulating bath 901 through the optical modulator 926 and the relaxing light expanding system 928. The relaxing light 924 having entered the cell intersects with the probe lights 913 and 914 and the pump light 903.

The relaxing light optical system described above is arranged so that the probe lights 923 and 924 propagate through the cell along an −z direction in the coordinate system illustrated in FIG. 9.

Next, regarding components of the optically pumped magnetometer according to this embodiment, points different from those of the embodiments described above are described more specifically. Portions that are not particularly described below are the same as those of the embodiments described above.

[1] Isothermal Insulating Bath 901

A glass cell is installed in the isothermal insulating bath 901. Potassium atoms and rubidium atoms are sealed in the glass cell so that the spin polarization of alkali metal atoms in a traveling direction of the pump light is made spatially uniform. As other available combinations of the alkali metal atoms, there are given a combination of potassium and cesium and a combination of rubidium and cesium. The combination in which the magnitudes of magnetic rotation ratios become the same, that is, the combination of isotopes having the same nuclear spin I is only a combination of ³⁹K and ⁸⁷Rb in which I=3/2. Further, of the alkali metal atoms, potassium has the smallest scattering cross-section with respect to spin polarization destruction caused by the collision between the same kind of the alkali metal atoms and the collision between the alkali metal atom and the helium atom, and rubidium has the second smallest scattering cross-section. Therefore, as a combination of the alkali metal atoms, a combination of the potassium atom and the rubidium atom is most preferred.

Further, rubidium has a vapor pressure larger than that of potassium at the same temperature, and hence it is preferred that the sealed amount of the rubidium atoms in the cell be smaller than that of the potassium atoms. Further, besides the potassium atoms and the rubidium atoms, helium gas and nitrogen gas are sealed in the cell as a buffer gas and a quencher gas, respectively.

[2] Pump Light Optical System

The pump light source 902 includes a light frequency stabilization unit configured to fix the wavelength of the pump light 903 to the D1 transition resonance wavelength (795.0 nm) of the rubidium atom. The pump light 903 is converted so as to have a circular polarization component by a quarter wavelength plate or the like. The pump light 903 that is circularly-polarized light enters the cell in the isothermal insulating bath 901 through the optical window, and spin-polarizes the rubidium atoms in the cell.

When the spin-polarized rubidium atoms collide with the potassium atoms, a spin exchange interaction occurs, and the spin polarization is given to the potassium atoms. Therefore, the potassium atoms can also be polarized by polarizing the rubidium atoms. A wavelength difference between the D1 transition resonance wavelength of the rubidium atom, and the D1 transition resonance wavelength (770.1 nm) and the D2 transition resonance wavelength (766.7 nm) of the potassium atom is sufficiently large as compared to an absorption line width (≈10 GHz) in the presence of a buffer gas. Thus, the pump light 902 is hardly absorbed by the potassium atom.

Further, when the rubidium atoms are polarized, the rubidium atoms do not absorb the pump light 903 that is circularly-polarized light. Therefore, the absorption rate of the pump light 903 is decreased when the polarization ratio of a rubidium atomic group is increased. As a result, when the intensity of the pump light 903 is sufficiently large, even when the rubidium atoms in the intersection region with the probe light 913 are spin-polarized, attenuation does not occur, and the rubidium atoms in the intersection region with the probe light 914 can be sufficiently spin-polarized.

By setting the atomic number density of the rubidium atom to be smaller than that of the potassium atom, the spin polarization ratio of a potassium atomic group can be made smaller than that of a rubidium atomic group. That is, the spin polarization ratio of the potassium atom caused by the spin exchange collision from the rubidium atom becomes smaller than that of the rubidium atomic group even when the rubidium atomic group is completely spin-polarized. Therefore, the spin polarization ratio of the potassium atom can be lowered to the vicinity of the polarization ratio (≈0.5) where magnetic field sensitivity becomes maximum.

The pump light 903 having been transmitted through the cell is optically terminated in the isothermal insulating bath 901. Alternatively, the pump light 903 may be terminally-processed after being output from the isothermal insulating bath 901 through the optical window.

[3] Relaxing Light Optical System

The relaxing light source 921 includes a light frequency stabilization unit configured to fix the wavelength of the relaxing light 923 to the D1 transition resonance wavelength (770.1 nm) or the D2 transition resonance wavelength (766.7 nm) of the potassium atom. The relaxing light source 922 includes a light frequency stabilization unit configured to fix the wavelength of the relaxing light 924 to the D1 transition resonance wavelength (770.1 nm) or the D2 transition resonance wavelength (766.7 nm) of the potassium atom. The relaxing lights 923 and 924 may be obtained by dividing light from the same light source into two. Further, in the case where the relaxing light intensity is sufficient, the wavelength of the relaxing light may be detuned to some degree from the transition resonance wavelength.

After the relaxing lights 923 and 924 are modulated by the optical modulators 925 and 926, the relaxing lights 923 and 924 are formed into beams by the relaxing light expanding systems 927 and 928 so as to simultaneously strike the probe lights 913 and 914. It is sufficient that the relaxing light expanding system 927 cause the relaxing light 923 to be radiated to the intersection regions between the probe light 913 and the pump light 903 and between the probe light 914 and the pump light 903, or may be configured to divide the relaxing light 923 into two lights with a beam splitter or the like and cause the relaxing lights to be radiated to the probe lights 913 and 914. Further, the relaxing light expanding system 928 may also be configured to divide the relaxing light 923 into two lights with a beam splitter or the like and cause the relaxing lights to be radiated to the probe lights 913 and 914.

The polarized lights of the relaxing lights 923 and 924 may be circularly-polarized lights, elliptically-polarized lights, or non-polarized lights. However, in order to accelerate the spin relaxation of the potassium atom efficiently with the relaxing light having constant light intensity, linear polarization is preferred. Further, the wavelengths of the relaxing lights 922 and 923 may be fixed to the D1 transition resonance wavelength (795.0 nm) or the D2 transition resonance wavelength (780.2 nm) of the rubidium atom. However, in this case, the relaxation of the spin polarization of the rubidium atom with the relaxing lights 922 and 923 relaxes the spin polarization of the potassium atom through a spin exchange interaction, and hence the efficiency thereof is not satisfactory. Therefore, in order to accelerate the spin relaxation of the potassium atom efficiently with the relaxing light having constant light intensity, it is preferred that the wavelengths of the relaxing lights 922 and 923 be matched with the D1 transition resonance wavelength or the D2 transition resonance wavelength of the potassium atom.

The relaxing lights 923 and 924 having been transmitted through the cell in the isothermal insulating bath 901 are optically terminated in the isothermal insulating bath 901. Alternatively, the relaxing lights 923 and 924 may be optically terminated after being output from the isothermal insulating bath 901 through the optical window. The number of relaxing light optical systems is not limited to two, and three or more relaxing light optical systems may be used.

[4] Probe Light Optical System

The wavelength of the probe light 913 output from the probe light source 911 and the wavelength of the probe light 914 output from the probe light source 912 take dephasing of about several GHz from the D1 transition resonance wavelength of the potassium atom so that a signal response becomes maximum. The value of dephasing that maximizes the signal response depends on the buffer gas pressure and temperature of the cell in the isothermal insulating bath 901. In order to stably keep this wavelength, the probe light sources 911 and 912 may include a stabilization unit, e.g., an external resonator. The probe lights 913 and 914 are respectively converted into linearly-polarized lights with a linear polarizer or the like. The wavelengths of the probe lights 913 and 914 that take dephasing of about several GHz from the D1 transition resonance wavelength of the potassium atom are also sufficiently away from the D1 transition resonance wavelength and the D2 transition resonance wavelength of the rubidium atom. Therefore, the probe lights 913 and 914 have polarization planes thereof subjected to Faraday rotation in proportion to the magnitude of an x component of the spin polarization of the potassium atom rotated by a magnetic field to be measured without being subjected to the absorption by the rubidium atom or Faraday interaction.

A combination of the wavelength of the pump light 903 and the wavelengths of the probe lights 913 and 914 is not limited to the combination described above. For example, the wavelength of the pump light 903 may be matched with the D1 transition resonance wavelength of the potassium atom, and the wavelengths of the probe lights 913 and 914 may be set to wavelengths taking dephasing of about several GHz from the D1 transition resonance wavelength of the rubidium atom so that the signal response becomes maximum. In this case, it is efficient and preferred that the wavelengths of the relaxing lights 923 and 924 be matched with the D1 transition resonance wavelength of the rubidium atom or the D2 transition resonance wavelength of the rubidium atom, to thereby relax the spin polarization of the rubidium atom directly without the spin exchange interaction.

[5] Polarization Measurement System

As illustrated in FIG. 10, the polarization measurement system 918 configured to measure the polarization of the probe light 913 includes a polarization splitter 1001, photodetectors 1003 and 1004, a differential circuit 1007, and demodulators 1009 and 1010. Further, the polarization measurement system 917 configured to measure the polarization of the probe light 914 includes a polarization splitter 1002, photodetectors 1005 and 1006, a differential circuit 1008, and demodulators 1011 and 1012.

When demodulation is performed by the demodulator 1009 at the same frequency as the modulation frequency in the optical modulator 925, a magnetic signal in the intersection region between the probe light 913 and the relaxing light 923 can be taken out. Further, when demodulation is performed by the demodulator 1010 at the same frequency as the modulation frequency in the optical modulator 926, a magnetic signal in the intersection region between the probe light 913 and the relaxing light 924 can be taken out. Further, when demodulation is performed by the demodulator 1011 at the same frequency as the modulation frequency in the optical modulator 925, a magnetic signal in the intersection region between the probe light 914 and the relaxing light 923 can be taken out. Further, when demodulation is performed by the demodulator 1012 at the same frequency as the modulation frequency in the optical modulator 926, a magnetic signal in the intersection region between the probe light 914 and the relaxing light 924 can be taken out. Thus, in the optically pumped magnetometer 900 according to this embodiment, in the coordinate system illustrated in FIG. 9, a magnetic field distribution of four points on an x-y plane of a magnetic field B_{z} to be measured of a z direction component can be measured.

In this embodiment, an example of a hybrid cell that uses the D1 transition resonance wavelength of the rubidium atom as the wavelength of the pump light and uses the D1 transition resonance wavelength of the potassium atom as the wavelength of the probe light is described. In such hybrid cell, the D1 transition resonance wavelength of the potassium atom may be used as the wavelength of the pump light, and the D1 transition resonance wavelength of the rubidium atom may be used as the wavelength of the probe light. As described in the description regarding the cell, in this case, it is effective for configuring a sensor having high sensitivity to use a cell with such a sealed amount that the density of the potassium atom becomes higher than that of the rubidium atom at an operating temperature.

As described above, according to this embodiment, different modulations are performed with respect to the relaxing lights that enter different positions in the cell, and hence magnetic information of the different positions can be transmitted with the probe light. With this, magnetic information of spatially different places can be separated and measured simultaneously with one probe light. Further, through use of a plurality of probe lights and a plurality of relaxing lights, magnetic information can be separated and measured simultaneously in each of intersection portions between the probe lights and the pump lights.

### The Sixth Embodiment

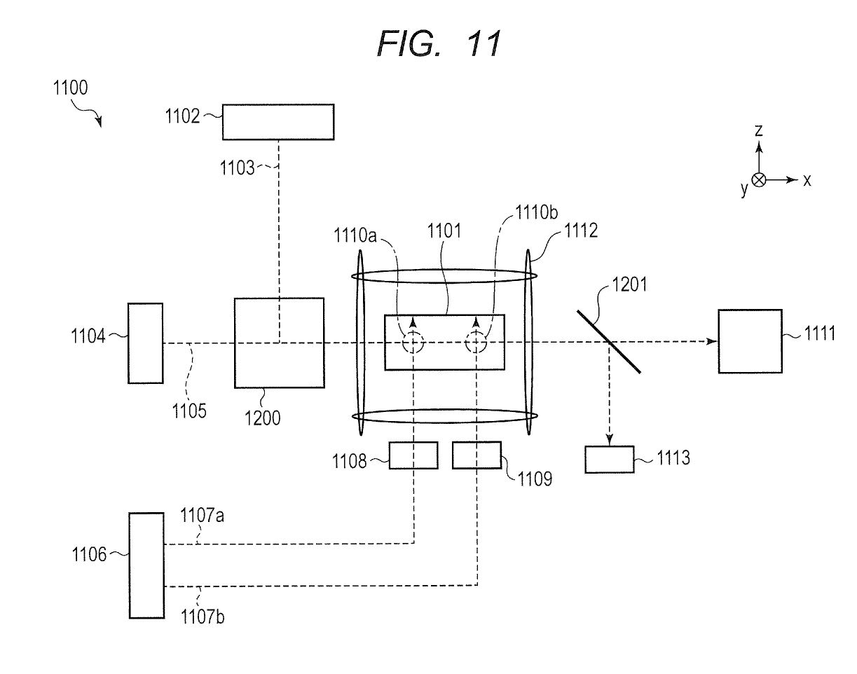

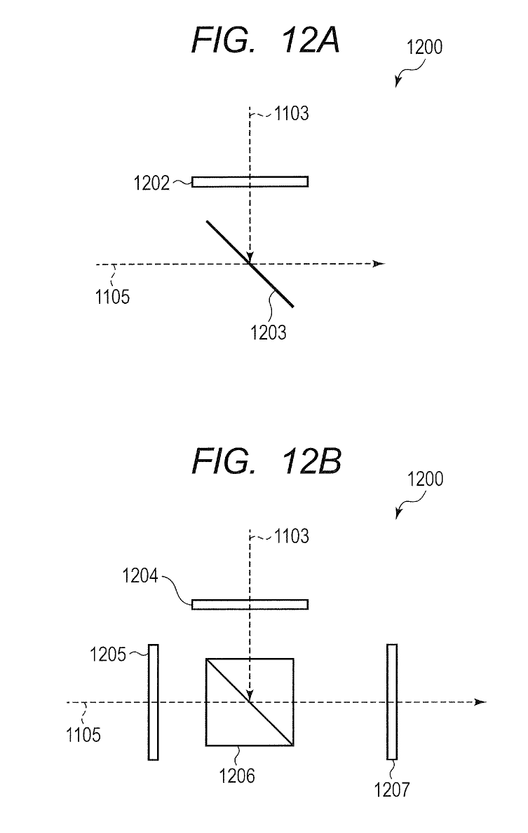

An optically pumped magnetometer and a magnetic sensing method according to the sixth embodiment of the present invention are described with reference to FIG. 11, FIG. 12A, and FIG. 12B. Also in this embodiment, in the same way as in the fifth embodiment, a combination of a plurality of kinds of alkali metal atoms is used, and for example, a potassium atom and a rubidium atom are used.

FIG. 11 is a diagram illustrating a schematic configuration of an optically pumped magnetometer according to this embodiment. FIG. 12A and FIG. 12B are diagrams illustrating schematic configurations of a light superposition part.

As illustrated in FIG. 11, an optically pumped magnetometer 1100 according to this embodiment includes an isothermal insulating bath 1101, a pump light optical system 1102, a probe light optical system 1104, a relaxing light optical system 1106, optical modulators 1108 and 1109, a polarization measurement system 1111, a bias magnetic field adjusting coil 1112, a light superposition part 1200, and a light separation part 1201. A cell containing a potassium atom and a rubidium atom is arranged in the isothermal insulating bath 1101. Further, the bias magnetic field adjusting coil 1112 is arranged on the periphery of the isothermal insulating bath 1101.

The pump light source 1102 includes a light frequency stabilization unit configured to fix the wavelength of pump light 1103 to the D1 transition resonance wavelength (795.0 nm) of the rubidium atom. The pump light 1103 output from the pump light optical system 1102 has a circular polarization component, and the pomp light 1103 is arranged so as to be superposed on probe light 1105 in the light superposition part 1200. The pump light 1103 superposed on the probe light 1105 propagates through the cell in the isothermal insulating bath 1101 along an x direction in a coordinate system illustrated in FIG. 11.

The wavelength of the probe light 1105 output from the probe light optical system 1104 takes dephasing of several GHz from D1 transition resonance wavelength (770.1 nm) of the potassium atom so that a signal response becomes maximum. In the light superposition part 1200, the probe light 1105 has a linear polarization component and is arranged so as to be superposed on the pump light 1103. The probe light 1105 superposed on the pump light 1103 propagates through the cell in the isothermal insulating bath 1101 along the x direction in the coordinated system illustrated in FIG. 11.

Relaxing light 1107a having a linear polarization component output from the relaxing light optical system 1106 and relaxing light 1107b having a linear polarization component output from the relaxing light optical system 1106 enter the cell in the isothermal insulating bath 1101 through the optical modulators 1108 and 1109, respectively. The relaxing light 1107a that has entered the cell intersects with the probe light 1105 and the pump light 1103 in a measurement region 1110a, and the relaxing light 1107b interests with the probe light 1105 and the pump light 1103 in a measurement region 1110b. The relaxing light optical system 1106 is arranged so that the relaxing lights 1107a and 1107b propagate through the cell along a z direction in the coordinate system illustrated in FIG. 9.

Next, regarding components of the optically pumped magnetometer according to this embodiment, points different from those of the embodiments described above are described more specifically. Portions that are not particularly described below are the same as those of the embodiments described above.

[1] Light Superposition Part and Light Separation Part

As illustrated in FIG. 12A, the light superposition part 1200 includes a quarter wavelength plate 1202 and a dichroic mirror (wavelength discrimination unit) 1203.

As the dichroic mirror 1203, a dichroic mirror designed so as to reflect light having a wavelength of the pump light 1103 and transmit light having a wavelength of the probe light 1105 can be used. The wavelength discrimination unit, e.g., a dichromic mirror, can discriminate two lights with higher accuracy when the two lights have a larger wavelength difference. A wavelength difference of 25 nm between the pump light and the probe light is sufficient for discriminating the two lights.

The pump light 1103 that enters the light superposition part 1200 is linearly-polarized. The pump light 1103 is converted so as to have a circular polarization component by the quarter wavelength plate 1202 and is reflected by the dichroic mirror 1203.

The probe light 1105 that enters the light superposition part 1200 is linearly-polarized. The probe light 1105 is adjusted so as to be transmitted through the dichroic mirror 1203 and output from the light superposition part 1200 in a state of being superposed on the pump light 1103.

Further, as illustrated in FIG. 12B, the light superposition part 1200 can also be constructed by using a polarized beam splitter 1206 and a phase shifter 1207. As the phase shifter 1207, a phase shifter designed so as to serve as a quarter wavelength plate at the wavelength of the pump light 1103 and serve as a half wavelength plate at the wavelength of the probe light 1105 can be used.

The pump light 1103 is adjusted for polarization thereof by the half wavelength plate 1204 so as to be reflected by the polarized beam splitter 1206. Further, the probe light 1105 is adjusted for polarization thereof by the half wavelength plate 1205 so as to be transmitted through the polarized beam splitter 1206. The pump light 1103 having been reflected by the polarized beam splitter 1206 is adjusted for polarization thereof by the phase shifter 1207 so as to have a circular polarization component, and further the probe light 1105 having been transmitted through the polarized beam splitter 1206 is adjusted for polarization thereof by the phase shifter 1207 so as to remain linearly-polarized light.

Also in the light separation part 1201, a dichroic mirror designed so as to reflect light having a wavelength of the pump light 1103 and transmit light having a wavelength of the probe light 1105 can be used. When the circularly-polarized pump light 1103 enters the polarization measurement system 1111, a response signal to a magnetic field does not increase but shot noise of the light increases, with the result that an SN ratio thereof decreases. In order to avoid the decrease in SN ratio, the pump light 1103 and the probe light 1105 are separated from each other by the light separation part 1201.

When a dichroic mirror is used as the light separation part 1201, the dichroic mirror is arranged so as to reflect the pump light 1103 and transmit only the probe light 1105 to guide the probe light 1105 into the polarization measurement system 1111. The reflected pump light 1103 is absorbed by an optical terminator 1113. Alternatively, the dichroic mirror may be configured to reflect the pump light 1103 by 180° to cause the pump light 1103 to enter the cell again, to thereby gain a polarization ratio. In the arrangement in which the pump light 1103 is reflected by 180°, when the intensity of the pump light 1103 is high, it is necessary to use an isolator so that the pump light 1103 does not return to the pump light optical system 1102. Further, a sharp cut filter that transmits only light having a particular wavelength band can also be used. In this case, the sharp cut filter can be arranged at any angle within a range of keeping wavelength characteristics such that the pump light 1103 is absorbed and only the probe light 1105 is transmitted, and it is not necessary that the pump light 1103 be optically terminated.

In the case of using a cell in which only potassium atoms or only rubidium atoms are sealed as alkali metal atoms, the wavelength of the pump light takes dephasing of several GHz from the D1 transmission resonance wavelength and the wavelength of the probe light takes dephasing of several GHz from the D1 transition resonance wavelength, resulting in a combination with a small wavelength difference. Therefore, it is difficult to separate two lights with the wavelength discrimination unit, e.g., a dichroic mirror. Further, a configuration in which the wavelength of the probe light takes dephasing of several GHz from the D2 transition resonance wavelength is also considered. However, the light absorption of the D2 transition resonance wavelength is higher than that of the D1 transition resonance wavelength, and hence there is a drawback in that a response to a magnetic field may become weak. Further, the wavelength difference between the D1 transition resonance wavelength and the D2 transition resonance wavelength of the potassium atom is about 3 nm, and the wavelength difference between the D1 transition resonance wavelength and the D2 transition resonance wavelength is about 15 nm. Those wavelength differences are smaller than that of this embodiment, and it becomes relatively difficult to separate two lights with the wavelength discrimination unit, e.g., a dichroic mirror. Further, the light superposition part 1200 may also be replaced by a configuration using a half mirror, but in this case, light intensities of the pump light 1103 and the probe light 1105 may decrease by half when the pump light 1103 and the probe light 1105 are superposed on each other.

Therefore, in this embodiment using the probe light and the pump light superposed on each other, a configuration is desired, which uses a cell containing a potassium atom and a rubidium atom and uses a unit capable of discriminating lights having particular wavelengths, e.g., a dichroic mirror, in the light superposition part 1200.

[2] Bias Magnetic Field Adjusting Coil

The bias magnetic field adjusting coil 1112 is installed in a magnetic shield for reducing a magnetic field that enters from an external environment (not shown).

The bias magnetic field adjusting coil 1112 is used for operating a magnetic field environment on the periphery of the cell in the isothermal insulating bath 1101. As a specific example of the bias magnetic field adjusting coil 1112, there is given, for example, triaxial Helmholtz coils. The bias magnetic field adjusting coil 1112 is used to apply a bias magnetic field in a direction (x direction in FIG. 11) parallel to the pump light 1103 so that the measurement frequency and the Larmor frequency are matched with each other to be resonated. Then, magnetic fields in directions (y direction and z direction in FIG. 11) orthogonal to the probe light 1105 and the pump light 1103 can be measured.

In this embodiment, an example is described in which the D1 transition resonance wavelength of the rubidium atom is used as the wavelength of the pump light, and the D1 transition resonance wavelength of the potassium atom is used as the wavelength of the probe light. In such hybrid cell, the D1 transition resonance wavelength of the potassium atom can also be used as the wavelength of the pump light, and the D1 transition resonance wavelength of the rubidium atom can also be used as the wavelength of the probe light.

As described above, according to this embodiment, different modulations are performed with respect to relaxing lights that enter different positions in the cell, and hence magnetic information of each of the different positions can be transmitted with the probe light. With this, magnetic information of spatially different places can be separated and measured simultaneously using one probe light. Further, through use of a plurality of probe lights and a plurality of relaxing lights, magnetic information can be separated and measured simultaneously in each of intersection portions between the probe lights and the pump lights.

### MODIFIED EMBODIMENT

The present invention is not limited to the above-mentioned embodiments and can be variously modified.

In the foregoing, some embodiments to which the present invention can be applied are merely described. However, the present invention does not exclude the case where those embodiments are altered or modified appropriately without departing from the spirit of the present invention.

According to the present invention, magnetic information of spatially different places can be separated and measured simultaneously using one probe light.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-143805, filed Jul. 21, 2015, which is hereby incorporated by reference herein in its entirety.

What is claimed is:

1. An optically pumped magnetometer, comprising:
at least one cell containing alkali metal atoms;
a pump light optical system configured to cause pump light having a circular polarization component to enter the at least one cell;
a probe light optical system configured to cause probe light having a linear polarization component to enter the at least one cell so as to intersect with the pump light in the at least one cell;
a relaxing light optical system configured to cause a plurality of relaxing lights for relaxing spin polarization of an electron of the alkali metal atoms to enter different positions in a region in which the pump light and the probe light intersect with each other;
a detection unit configured to detect the probe light having intersected with the pump light and the plurality of relaxing lights, to thereby output a detection signal; and
an information acquisition unit configured to acquire information on a magnetic field intensity of each of the different positions from the detection signal,
wherein at least one of periods or phases of time change in intensity or wavelength of the plurality of relaxing lights is different from one another.

2. An optically pumped magnetometer according to claim 1, wherein the optical pumped magnetometer comprises a modulation unit configured to perform modulation so that at least one of the periods of time change in intensity or wavelength of the plurality of relaxing lights, or the phases of time change in intensity or wavelength of the plurality of relaxing lights is different from one another.

3. An optically pumped magnetometer according to claim 2, wherein the modulation unit is configured to modulate any one of the intensity and the wavelength of each of the plurality of relaxing lights.

4. An optically pumped magnetometer according to claim 2, wherein the plurality of relaxing lights that enter the different positions are respectively modulated by application of different modulation frequencies.

5. An optically pumped magnetometer according to claim 4, wherein the different modulation frequencies of the modulation unit is equal to or higher than 100 Hz.

6. An optically pumped magnetometer according to claim 5, wherein the different modulation frequencies of the modulation unit is equal to or higher than 1 kHz.

7. An optically pumped magnetometer according to claim 2, wherein the information acquisition unit comprises a demodulation unit configured to demodulate the detection signal at the same frequency as a modulation frequency applied in the modulation unit.

8. An optically pumped magnetometer according to claim 1, wherein the plurality of relaxing lights that enter the different positions are respectively modulated at different phases.

9. An optically pumped magnetometer according to claim 1, wherein the plurality of relaxing lights that enter the different positions are respectively modulated at different pulse widths.

10. An optically pumped magnetometer according to claim 1, wherein each of the plurality of relaxing lights that enter the region in which the pump light and the probe light intersect with each other has one of a wavelength resonated with a D1 transition of the alkali metal atom and a wavelength resonated with a D2 transition of the alkali metal atom.

11. An optically pumped magnetometer according to claim 10, wherein each of the plurality of relaxing lights that enter the region in which the pump light and the probe light intersect with each other has the wavelength resonated with the D1 transition of the alkali metal atom.

12. An optically pumped magnetometer according to claim 1, wherein the alkali metal atom comprises at least one kind selected from the group consisting of potassium, rubidium, and cesium.

13. An optically pumped magnetometer according to claim 12, wherein the alkali metal atom comprises potassium and rubidium.

14. An optically pumped magnetometer according to claim 13, wherein the rubidium contained in the at least one cell has an atomic number density smaller than an atomic number density of the potassium contained in the at least one cell.

15. An optically pumped magnetometer according to claim 1, wherein the probe light optical system is configured to cause a plurality of the probe lights to enter the at least one cell so as to intersect with the plurality of relaxing lights at different positions.

16. An optically pumped magnetometer according to claim 1, wherein the pump light optical system is configured to cause the pump light to enter the at least one cell from the same direction as a direction of the probe light.

17. An optically pumped magnetometer according to claim 1, wherein the relaxing light optical system is configured to cause the plurality of relaxing lights to enter the at least one cell from the same direction as a direction of the pump light.

18. An optically pumped magnetometer according to claim 1, comprising a plurality of cells,
wherein the relaxing light optical system is configured to cause at least one of the plurality of relaxing lights to enter each of the plurality of cells, and
wherein the probe light is configured to intersect with the at least one of the plurality of relaxing lights in each of the plurality of cells.

19. A magnetic sensing method, comprising:
causing pump light having a circular polarization component to enter at least one cell containing alkali metal atoms, causing probe light having a linear polarization component to enter the at least one cell so as to intersect with the pump light in the at least one cell, and causing a plurality of relaxing lights to enter different positions in a region in which the pump light and the probe light intersect with each other, at least one of periods or phases of time change in intensity or wavelength of the plurality of relaxing lights being different from one another;
detecting the probe light having passed through the at least one cell to output a detection signal; and
calculating information on a magnetic field intensity at each of the different positions from the detection signal.

20. A magnetic sensing method according to claim 19, wherein each of the plurality of relaxing lights intersecting with the probe light has one of a wavelength resonated with a D1 transition of the alkali metal atom and a wavelength resonated with a D2 transition of the alkali metal atom.
